(19) United States
(12) Patent Application Publication
(10) Pub. No.: US 2026/0213129 A1
(43) Pub. Date: Jul. 23, 2026

(54) CHARGED PARTICLE APPARATUS WITH IMPROVED VACUUM CHAMBER

(71) Applicant: ASML Netherlands B.V., Veldhoven (NL)

(72) Inventors: Qingpo XI, Fremont, CA (US); Zhidong DU, San Jose, CA (US); Le YU, San Jose, CA (US); Juying DOU, San Jose, CA (US); Weiming REN, San Jose, CA (US); Xuerang HU, San Jose, CA (US); Zhiming ZHANG, San Jose, CA (US); Mingkang WANG, Milpitas, CA (US); Liang DONG, Newark, CA (US); Zizhou GONG, San Jose, CA (US)

(73) Assignee: ASML Netherlands B.V., Veldhoven (NL)

(21) Appl. No.: 19/144,022

(22) PCT Filed: Dec. 21, 2023
(86) PCT No.: PCT/EP2023/087440

§ 371 Date: Jun. 27, 2025

Related U.S. Application Data
(60) Provisional application No. 63/435,981, filed on Dec. 29, 2022.
(60) Provisional application No. 63/529,346, filed on Jul. 27, 2023.
(60) Provisional application No. 63/606,549, filed on Dec. 5, 2023.

(51) Int. Cl. H01J 37/317; H01J 37/09; H01J 37/18

(52) U.S. Cl. CPC H01J 37/3177; H01J 37/09; H01J 37/18; H01J 2237/0453

(57) ABSTRACT

An electron beam source is configured in an ultra-high vacuum chamber. Gas molecules are prevented from reaching an emission tip of the electron source by a differential aperture system. The differential aperture system may comprise at least one aperture plate configured to seal a region of the vacuum chamber from an outgassing source so that gas molecules may only pass from the source to the region by holes in the at least one aperture plate.

### CROSS-REFERENCE TO RELATED APPLICATIONS

This application claims priority of U.S. application 63/435,981 which was filed on Dec. 29, 2022 and U.S. application 63/529,346 which was filed on Jul. 27, 2023 and U.S. application 63/606,549 which was filed on Dec. 5, 2023 which are incorporated herein in its entirety by reference.

### FIELD

The embodiments provided herein relate to charged-particle beam sources of charged-particle beam systems, and more particularly to an improved vacuum chamber for an electron beam source.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy, imaging resolution and yield in defect detection become more important. In a SEM, a beam of primary electrons having a relatively high energy is decelerated to land on a sample at a relatively low landing energy and is focused to form a probe spot thereon. Due to this focused probe spot of primary electrons, secondary electrons will be generated from the surface. The secondary electrons are detected by an electron detector to generate SEM images of the sample.

Quality and resolution of the images are greatly influenced by the stability of the primary electron beam generated by an electron source and the electromagnetic (EM) field uniformity of the electron optical environment. For example, a thermionic electron emission source or a cold field emission source may be used to provide electrons for high resolution imaging in SEM systems. However, contamination of the emission source environment and a spatially non-uniform EM field environment may degrade performance. Therefore, maintaining a high level of vacuum cleanliness and good uniformity is desired for the high imaging resolution and high inspection throughput.

### SUMMARY

The embodiments provided herein disclose a charged-particle beam apparatus, and more particularly an improved vacuum chamber for electron sources.

Some embodiments of the present disclosure provide an apparatus. The apparatus may comprise: a vacuum chamber; a vacuum pump; a source located inside the vacuum chamber and configured to emit charged particles, an electrode configured to accelerate the charged particles to generate a charged particle beam; and a plurality of differential aperture plates. At least one of the plurality of differential aperture plates may comprise a surface portion that is not perpendicular to an axis of the charged particle beam. The surface portion may be configured to guide gas molecules to the vacuum pump.

Some embodiments of the present disclosure provide an apparatus. The apparatus may comprise: a vacuum chamber; a vacuum pump; a source located inside the vacuum chamber and configured to emit charged particles; an electrode configured to accelerate the charged particles to generate a charged particle beam; and a plurality of differential aperture plates arranged along an axial direction of the charged particle beam. Each differential aperture plate may comprise a hole. At least two differential aperture plates of the plurality of differential aperture plates may comprise holes of different sizes. A size of the holes of the at least two differential aperture plates may increase with increasing distance from the source.

Some embodiments of the present disclosure provide an apparatus. The apparatus may comprise: a vacuum chamber; a source located inside the vacuum chamber and configured to emit charged particles; an extractor at a first potential located downstream of the source, the extractor being at the first voltage to enable extraction of the electrons from the source; an anode, including multiple apertures each configured to generate a beamlet of charged particles from the emitted charged particles, located downstream from the extractor, the anode being at a second potential different from the first potential and causing energies of the beamlet of charged particles to change; a booster tube configured to reduce or eliminate disturbance of the beamlets due to electric fields of structures near to the booster tube, the booster tube being located downstream of the anode; and a differential aperture plate between the anode and the booster tube, the differential aperture plate being configured to reduce a flow of gas from the booster tube and flowing towards the source, the aperture plate being at the second potential.

Some embodiments of the present disclosure provide an apparatus. The apparatus may comprise: a vacuum chamber; a source located inside the vacuum chamber and configured to emit charged particles; an electrode configured to accelerate the charged particles to generate a charged particle beam; and a booster tube configured to surround the charged particle beam within the vacuum chamber. The booster tube may be configured to generate a uniform potential inside the booster tube. The booster tube may comprise an opening configured to allow gas molecules from inside the booster tube to pass to a region outside the booster tube. The region outside the booster tube may be adjacent to the booster tube in a radial direction perpendicular to an axis of the charged particle beam.

Some embodiments of the present disclosure provide an apparatus. The apparatus may comprise: a vacuum chamber; an emission source located inside the vacuum chamber and configured to emit charged particles; a first aperture plate comprising a first plurality of holes, the first aperture plate being configured to block a portion of the emitted charged particles and pass the remaining emitted charged particles as a plurality of charged particle beamlets; a second aperture plate comprising a second plurality of holes and configured to pass the plurality of charged particle beamlets without blocking further charged particles; and an outgassing source. The second aperture plate may be configured to reduce passage of gas molecules from the outgassing source to the emission source.

Some embodiments of the present disclosure provide an apparatus. The apparatus may comprise: a vacuum chamber; an emission source located inside the vacuum chamber and configured to emit charged particles; a first aperture plate comprising a first hole, the first aperture plate being configured to block a portion of the emitted charged particles and pass the remaining emitted charged particles as a charged particle beam; a second aperture plate comprising a second hole and configured to pass the charged particle beam without blocking further charged particles; and an outgassing source. The second aperture plate may be configured to reduce passage of gas molecules from the outgassing source to the emission source.

Some embodiments of the present disclosure provide an apparatus. The apparatus may comprise: a vacuum chamber; a source configured to emit charged particles; an electrode configured to accelerate the charged particles to generate a charged particle beam along an optical axis; a first booster tube configured to surround the optical axis within the vacuum chamber, the first booster tube comprising a first opening in a first sidewall of the first booster tube, the first opening being configured to allow gas molecules from inside the first booster tube to pass outside the first booster tube; and a second booster tube configured to surround the first booster tube within the vacuum chamber, the second booster tube comprising a second opening in a second sidewall of the second booster tube, the second opening being configured to allow gas molecules from inside the second booster tube to pass outside the second booster tube. The first opening may be completely offset from the second opening in a direction of the optical axis.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIGS. 1A-C are schematic diagrams illustrating an example charged-particle beam inspection system, consistent with embodiments of the present disclosure.

FIG. 2 is a schematic diagram illustrating an example configuration of an electron beam source, consistent with embodiments of the present disclosure.

FIG. 3 is a schematic diagram illustrating an example configuration of an electron beam source, consistent with embodiments of the present disclosure.

FIG. 4 is a schematic diagram illustrating an example configuration of an electron beam source, consistent with embodiments of the present disclosure.

FIGS. 5A-C is a schematic diagram illustrating an example configuration of an electron beam source, consistent with embodiments of the present disclosure.

FIGS. 6A-C is a schematic diagram illustrating an example configuration of an electron beam source, consistent with embodiments of the present disclosure.

FIG. 7 is a schematic diagram illustrating an example configuration of an electron beam source, consistent with embodiments of the present disclosure.

FIG. 8 is a is a flowchart illustrating an example method for detecting charged particles, consistent with embodiments of the disclosure.

FIG. 9 is a schematic diagram illustrating an example configuration of an electron beam source, consistent with embodiments of the present disclosure.

FIG. 10A is a schematic diagram illustrating example apertures according to a comparative embodiment.

FIG. 10B is a schematic diagram illustrating example apertures, consistent with embodiments of the present disclosure.

FIG. 11 is a schematic diagram illustrating an example configuration of an electron beam source, consistent with embodiments of the present disclosure.

FIG. 12 is a flowchart illustrating an example method for detecting charged particles, consistent with embodiments of the disclosure.

FIGS. 13A-C are schematic diagrams illustrating an example configuration of an electron beam source, consistent with embodiments of the present disclosure.

FIGS. 14A-B are schematic diagrams illustrating example configurations of skin depth frequencies of booster tubes, consistent with embodiments of the present disclosure.

FIG. 15 is a schematic diagram illustrating example opening configurations for booster tubes, consistent with embodiments of the present disclosure.

FIG. 16A is a schematic diagram illustrating example configurations of booster configurations for booster tubes, consistent with embodiments of the present disclosure.

FIG. 16B is a is a schematic diagram illustrating example nonuniformity measurements, consistent with embodiments of the present disclosure.

FIG. 17 is a is a schematic diagram illustrating an example opening configuration for booster tubes, consistent with embodiments of the present disclosure.

FIG. 18 is a schematic diagram illustrating an example opening configuration for booster tubes, consistent with embodiments of the present disclosure.

FIGS. 19A-B are schematic diagrams illustrating example opening configurations for booster tubes, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of silicon called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can fit on the substrate. For example, an IC chip in a smartphone can be as small as a thumbnail and yet may include over 10 billion transistors, the size of each transistor being less than 1/1000th the size of a human hair.

Making these ICs with so many extremely small transistors is a complex, time-consuming, and expensive process, often involving hundreds of individual manufacturing steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection can be carried out using a scanning charged-particle microscope such as, e.g., a scanning electron microscope (SEM). A SEM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate one or more inspection images. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

An electron emission source typically includes a negatively-charged tip (cathode) that provides electrons for the electron beam. For example, the tip may be a tungsten filament or point, or it may be a crystal such as LaB₆ or CeB₆. The tip may be heated (known as thermionic emission) or placed in a strong electric field (known as field emission) to cause the electrons to be emitted from the tip surface. The electrons may be extracted from the tip and accelerated in the beam direction by a positively-charged electrode plate (anode) and through an aperture in the anode towards downstream electron optics. In some embodiments, the extraction may be performed by a separate extractor electrode upstream of the anode. In some embodiments, the extractor may be held at a first potential, and the anode may be held at a second potential. The first and second potential may be the same or different.

The performance of emission tips can be significantly degraded by contamination from gas molecules on their surface. Therefore, emission sources may include an ultra-high vacuum chamber that may be regularly shut down for cleaning. To minimize the frequency of cleaning operations, reduce maintenance costs, and extend the tip lifetime, it is desirable to either pump the molecules away or block them from reaching the tip. Some components in electron beam systems may hamper the ability to do one or the other.

First, to maintain a desired energy level in the electron beam(s) as it travels from the anode to downstream electron optics or to prevent disturbance of the beam(s) from fields (e.g., magnetic, electric, electro-magnetic) resulting from, e.g., structures around the beam(s) (among others), the electron beam(s) may be surrounded by a high-voltage tubular electrode, which may be referred to as a booster tube. The booster tube may isolate the beam(s) from external fields and prevent the external fields from disturbing the electron beam(s). However, the booster tube may also trap gas molecules in its interior, preventing the vacuum pumps from evacuating the chamber properly. The gas molecules may instead be funneled along the booster tube to pass through the anode aperture and towards the emission tip.

Additionally, an electron beam may fan out in a cone shape as it travels away from the emission tip and towards the anode aperture. Therefore, to allow enough electrons to pass through the aperture and produce a sufficiently strong beam current, the aperture can be made sufficiently large. But as the aperture size increases, the emission tip may be left more vulnerable to contaminating gases passing through the aperture and to the tip, such as gas emanating from the booster tube or elsewhere in the vacuum chamber.

Some embodiments of the present disclosure provide a high-vacuum electron beam source with aperture plates that efficiently direct unwanted gas molecules away from an emission tip. Some embodiments of the present disclosure comprise a vented booster tube. The booster tube may comprise holes, slits, or other pathways that allow gas molecules from inside the booster tube to escape before reaching the emission tip. In some embodiments, the holes, slits, or other pathways may be covered or otherwise compensated so that fields external to the booster tube do not disturb an electron beam or beams inside the booster tube.

For example, in some embodiments, to improve the uniformity of a static E field inside a vented booster tube, a multi-layered configuration having, e.g., an inner booster tube and an outer booster tube may be provided. Openings in each of the inner and outer booster tubes may be offset from each other so that external static E fields are isolated by at least one of the inner or outer booster tubes. A uniform E-field environment is created.

However, even in such a configuration, dynamic EM fields may penetrate the tube materials and be partially attenuated by them. Because the degree of attenuation may depend on the amount and type of material that each EM field line traverses, the openings in each of the inner and outer booster tubes may produce EM field nonuniformities in the vicinity of the electron beam. Therefore, some embodiments of the present disclosure provide a multi-layered configuration in which the openings of the inner and outer booster tubes are staggered in a way that the net EM-field along the axial (z) direction of an electron beam path is substantially uniform in a cross-sectional plane (x, y) of the beam path. In this way, charged particles travelling along the axial (z) direction of the beam path at two different regions of the (x, y) plane may experience a substantially equal force along the way.

Some embodiments of the present disclosure comprise a differential aperture plate system. The differential aperture plate system may comprise a series of aperture plates arranged along the electron beam path from the emission tip. The spaces between the aperture plates may form gas channels configured to direct gas molecules toward a vacuum pump and away from the emission tip. In some embodiments, the series of plates may comprise gradually increasing aperture sizes to match a cone-shaped profile of the spreading electron beam. The aperture plates may be configured to provide multiple barriers between the emission tip and the rest of the vacuum chamber so that traveling gas molecules are less likely to reach the tip.

Some embodiments of the present disclosure provide one or more apertures located further downstream of the emission source. For example, the aperture may be provided at an outlet side of a vacuum chamber upstream of an outgassing source. The aperture may be located, e.g., near a gate valve or may be integral with the gate valve at the outlet side of the vacuum chamber. The outgassing source may be, e.g., a micro electromechanical system (MEMS) stack, a charged particle optical column, or other charged particle optical systems or related components. For example, the outgassing source may include wiring or mounting components, adhesives, lubricants, plastics, seals, etc. In some embodiments, an aperture may be located between charged particle optical elements within a vacuum chamber to subdivide a gas molecule path in the chamber.

Relative dimensions of components in drawings may be exaggerated for clarity. Within the following description of drawings the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detection systems and detection methods in systems utilizing electron beams. However, the disclosure is not so limited. Other types of charged particle beams (such as proton beams) may be similarly applied. For instance, systems and methods for detection may be used in other imaging systems, such as proton detection, ion detection, or the like. Therefore, while detectors in the present disclosure may be disclosed with respect to electron detection, some embodiments of the present disclosure may be directed to detecting other charged particles.

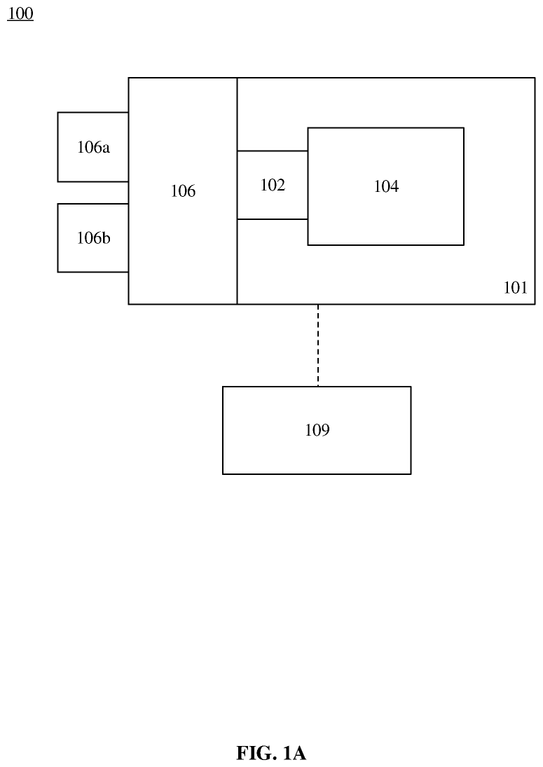

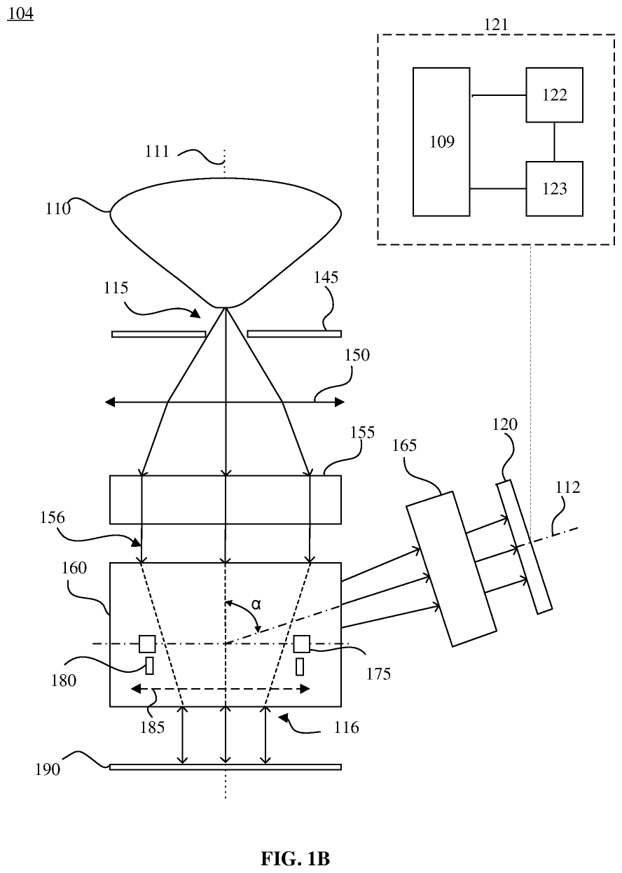

FIG. 1A illustrates an exemplary electron beam inspection (EBI) system 100 consistent with some embodiments of the present disclosure. EBI system 100 may be used for imaging. As shown in FIG. 1A, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1A as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

FIGS. 1B and 1C show a diagram illustrating a general representation of a SEM 104 that can be part of an inspection system, such as EBI system 100 of FIG. 1A. In this example, the SEM is an off-axis SEM, however some of the features described herein in connection with the image forming element are also applicable to on-axis SEMs. The SEM system may include a source 110 (or similar electron or radiation source), a gun aperture plate 145, a condenser lens 150, a source conversion unit 155, a primary projection system 160, and the target 190, all of which may be aligned with the primary axis 111. A beam separator 175 and a deflection scanning unit 180 may be placed inside the primary projection system 160. The primary projection system 160 may also include an objective lens 185. SEM 104 may also include a secondary imaging system 165 that may be aligned, along with a detector 120, with a secondary axis 112.

The source 110 may include a cathode, an extractor, or an anode, where primary electrons may be emitted from the cathode and extracted or accelerated to form a primary electron beam 115.

The gun aperture plate 145 may be used to block off peripheral electrons of primary electron beam 115 that are not in use to reduce the Coulomb effect, which may enlarge the size of each of the probe spots on the target 190 and therefore deteriorate inspection resolution.

The condenser lens 150 may be used to focus the primary electron beam 115. The electric currents of the electron beamlets downstream of the source conversion unit 155 may be varied by adjusting the focusing power of condenser lens 150 or by changing the radial sizes of the corresponding beam limit apertures within a beam limit aperture array 157 (shown in FIG. 1C) in the source conversion unit 155.

The source conversion unit 155 may include at least one image forming element 158 (shown in FIG. 1C) and the beam limit aperture array 157 discussed above. The image forming 158 element may have multiple micro lenses, micro deflectors, or stigmators to form parallel images (virtual or real) with multiple primary electron beamlets 156 from the primary electron beam 115, while the beam limit aperture array 157 may limit the number of electron beamlets 156. Source conversion unit 155 may comprise a plurality of micro electromechanical system (MEMS) devices.

The objective lens 185 in the primary projection system 160 can focus the electron beamlets onto the target 190 for inspection and can form a number of probe spots on the surface of the target 190 based on the number of the primary electron beamlets 156 provided by the source conversion unit 155.

The beam separator 175 in the primary projection system 160 may be a beam separator of Wien filter type generating an electrostatic dipole field and a magnetic dipole field. If they are applied, the force exerted by electrostatic dipole field on the electrons of the primary electron beamlets may be equal in magnitude and opposite in direction to the force exerted on the electrons by the magnetic dipole field, and therefore the electron beamlets may pass straight through the beam separator 175 with zero deflection angles.

The deflection scanning unit 180 in the primary projection system 160 may deflect the primary electron beamlets to scan the probes spots on the surface of the target 190. In response to incidence of the electron beamlets at the probe spots, the secondary electron beamlets 116 may be emitted from the target 190 and having electrons with a distribution of energies including secondary electrons (e.g., energies≤50 eV) and backscattered electrons (e.g., energies between 50 eV and landing energies of the electron beamlets). The beam separator 175 can direct the secondary electron beamlets towards the secondary imaging system 165, which in turn may focus the secondary electron beamlets onto a surface of the detector 120.

The beam separator 175 may be configured to deflect the secondary electron beamlets 116 by an angle α in the direction of the secondary imaging system 165. An angle α may be determined as the angle between the primary axis 111 and the secondary axis 112, as such, the angle α may represent the separation angle between the on-axis primary electron beam 115 and the secondary electron beamlets 116 that are directed by the beam separator 175 in the direction of the secondary imaging system 165 and the detector 120. In some implementations, the angle α may be set within a range of 5 to 25 degrees. The detector 120 can be a secondary electron (SE) detector that includes a single silicon PIN photodiode array.

Beam tool 104 may also include an image processing system 121 that includes an image acquirer 122, storage 123, and controller 109. Image acquirer 122 may include one or more processors. For example, image acquirer 122 may include a computer, server, mainframe host, terminals, personal computer, any kind of mobile computing devices, and the like, or a combination thereof. Image acquirer 122 may connect with a detector 120 of electron beam tool 104 through a medium such as an electrical conductor, optical fiber cable, portable storage media, IR, Bluetooth, internet, wireless network, wireless radio, or a combination thereof. Image acquirer 122 may receive a signal from detector 120 and may construct an image. Image acquirer 122 may thus acquire images of wafer 190. Image acquirer 122 may also perform various post-processing functions, such as generating contours, superimposing indicators on an acquired image, and the like. Image acquirer 122 may perform adjustments of brightness and contrast, or the like, of acquired images. Storage 123 may be a storage medium such as a hard disk, cloud storage, random access memory (RAM), other types of computer readable memory, and the like. Storage 123 may be coupled with image acquirer 122 and may be used for saving scanned raw image data as original images, and post-processed images. Image acquirer 122 and storage 123 may be connected to controller 109. In some embodiments, image acquirer 122, storage 123, and controller 109 may be integrated together as one control unit.

In some embodiments, image acquirer 122 may acquire one or more images of a sample based on an imaging signal received from detector 120. An imaging signal may correspond to a scanning operation for conducting charged particle imaging. An acquired image may be a single image including a plurality of imaging areas. The single image may be stored in storage 123. The single image may be an original image that may be divided into a plurality of regions. Each of the regions may include one imaging area containing a feature of wafer 190.

FIG. 1C shows a diagram illustrating a source conversion unit 155 used in the SEM described above, comprising the image forming element 158. When multiple electron beams or beamlets are used in an SEM, they may be generated from multiple sources or from a single source. If the electron beams are from multiple sources, multiple columns may scan and focus the electron beams onto the surface of the target, and the signals generated by the electron beams may be detected by detectors in the columns, respectively. An apparatus using beams from multiple sources may be referred to as a multi-column apparatus. If charged particle beams are from a single source, as in SEM 104 of FIG. 1B, a source conversion unit may be used to form multiple virtual or real images of the single beam source. The source conversion unit may have an electrically conductive layer with multiple apertures or opening that divide the charged particles from the single source into multiple electron beamlets. The source conversion unit may have many micro-elements (e.g., MEMS devices), typically organized in an array, that may influence the way of how to manipulate the electron beamlets to form multiple virtual or real images of the single source. The MEMS devices may be stacked as shown and may be referred to as a MEMS stack.

Further discussion of electron beam tools comprising MEMS stacks may be found in US Patent Application Publication No. 2020/0317504, which is incorporated by reference in its entirety.

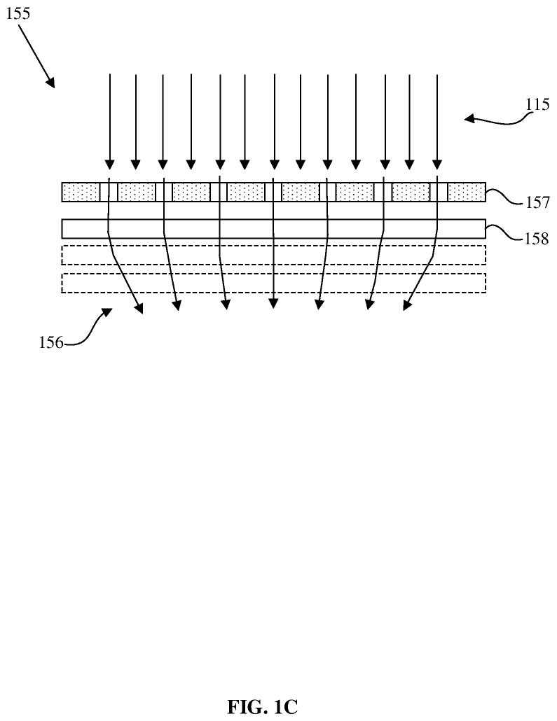

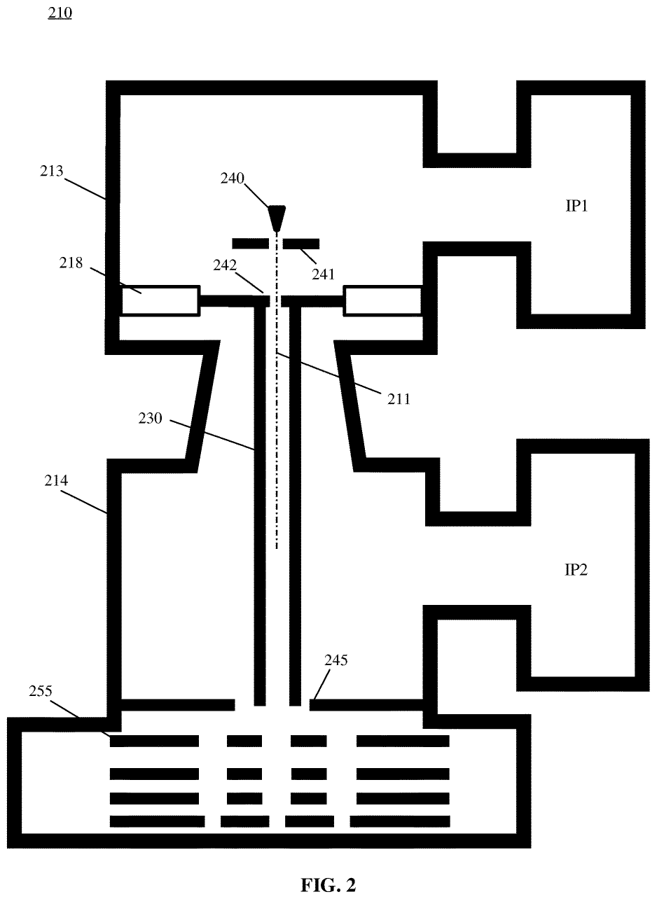

At the wafer side, a MEMS-based multi-beam inspection (MBI) tool may be employed in one of two configurations: wafer on high voltage (HV), or wafer on ground. The wafer on HV configuration may pose challenges due to added maintenance and risks associated with high voltage at the wafer stage. For example, an inspection tool may require, e.g., a 30 kV potential to achieve a 30 KeV e-beam. For wafer on HV, this means that other components of at the wafer side, such as bottom detectors, actuation systems, water cooling channels, etc. may float on HV as well. This may pose difficult engineering challenges, increase costs and risks of damage from unwanted discharges, etc. To reduce these costs and risks, a wafer on ground configuration may be desirable. To achieve a sufficient beam energy and electron optics performance in a wafer on ground configuration, a booster tube design may be employed as discussed below with respect to FIG. 2.

FIG. 2 illustrates an example electron beam source 210 and related components. Electron beam source 210 may comprise: an upper gun chamber 213; lower gun chamber 214; first ion pump IP1; second ion pump IP2; emission tip 240; first aperture plate 241; second aperture plate 242; aperture mount 218; booster tube 230; and gun aperture 245.

Electron beam source may comprise any type of emission source such as, e.g., a thermionic emission source, Schottky emission source, or a cold field emission source. Emission tip 240 may comprise a cathode formed as a tungsten filament, a tungsten tip, a crystal formed of LaB₆ or CeB₆, or any other suitable emission tip. In some embodiments, first aperture plate 241 may comprise an extractor electrode, and second aperture plate 242 may comprise an anode. As used herein, an aperture plate that functions as a certain electrode may alternatively be referred to as that electrode. For example, in FIG. 2, first aperture plate 241 may be referred to as extractor 241, and second aperture plate 242 may be referred to as anode 242. A power source (not shown) may be configured to generate a potential difference between the emission tip 240, extractor 241 and anode 242. For example, the power source may generate a first voltage at extractor 241 to extract electrons from emission tip 240. The power source may further be configured to generate a second voltage at anode 242 to accelerate the extracted electrons towards the anode aperture of aperture plate 242 to form electron beam 211. In some embodiments, first aperture plate 241 or second aperture plate 242 may be attached to a wall of upper gun chamber 213 by an insulating aperture mount 218. For example, aperture mount 218 may be formed of a ceramic or other non-conducting material. Aperture mount 218 may be annular or comprise another shape so as to surround second aperture plate 242 and divide the upper and lower gun chambers 213 and 214.

Booster tube 230 may comprise a substantially tubular electrode that surrounds the beam path of electron beam 211 within lower gun aperture 213. The power source, or a further power source (not shown), may apply a potential to booster tube 230 such as, e.g., 30 kV. In some embodiments, the potential may be, e.g., 1 kV, 5 kV, 10 kV, 50 kV, 100 kV or more. Booster tube 230 may be configured to accelerate the electrons in electron beam 211 and reduce the effect of coulomb interactions between them to produce a low-divergence, high-quality primary beam 211 at gun aperture 245.

Electron beam 211 may exit lower gun chamber 214 through gun aperture 245 and be incident on MEMS stack 255. MEMS stack 255 may comprise a plurality of layers comprising MEMS device for manipulating electron beam 211. In some embodiments, MEMS stack may form all or part of a source conversion unit, such as source conversion unit 155 in FIG. 1B. In some embodiments. MEMS stack 255 may comprise all or part of a primary projection system, such as primary projection system 160 of FIG. 1B. For example, in some embodiments MEMS stack 255 may comprise a beam separator or a deflection scanning unit, such as beam separator 175 or deflection scanning unit 180 of FIG. 1B. In some embodiments, MEMS stack 255 may comprise other electron optics. In some embodiments, electron beam 211 may be incident on components other than MEMS stack 255 as it exits lower gun chamber 214. Furthermore, the upper or lower gun chambers 213 and 214 may comprise additional elements such as further electrodes, lenses, apertures, MEMS devices and other electron optics.

Second aperture plate 242 may divide upper and lower gun chamber 213 and 214 into two separate vacuum chambers. Ion pump IP1 may be configured to maintain upper gun chamber at a first pressure, and ion pump IP2 may be configured to maintain lower gun chamber at a second pressure. In some embodiments, the first pressure and the second pressure may be substantially equal. In some embodiments, the first pressure may be lower than the second pressure. In some embodiments, the first pressure or the second pressure may be lower than, e.g., 1.0×10⁻⁰ Torr or 1.0×10⁻¹¹ Torr. Such ultra-high vacuum may maintain a high level of cleanliness to improve the lifetime and performance of emission tip 240. In some embodiments, first and second ion pumps IP1 and IP2 may comprise other vacuum devices such as, e.g., turbomolecular pumps, getter pumps, or similar vacuum devices.

Emission tip 240 can be degraded by the adsorption of gas molecules such as O₂, H₂O and other substances. Gas molecules may enter upper gun chamber 213 or lower gun chamber 214 by, e.g., outgassing from materials that are either inside the chambers 213/214 or in fluid communication with them. For instance, MEMS stack 255 may comprise a series of MEMS layers that are bonded to each other by an adhesive material. The adhesive material may comprise volatile compounds that cause much more outgassing than metals or other components of electron beam source 210. Furthermore, if those adhesives are not properly baked or otherwise cured, the level of outgassing during use may be increased.

The risk of outgassing may be compounded by an increasing need for larger beam currents. For example, some MEMS-based MBI tools may require a primary electron beam 240 having a relatively large half-angle of emission compared to other charged particle apparatus. Achieving a larger half-angle of emission necessitates larger aperture sizes in first aperture plate 241, second aperture plate 242, and gun aperture 245. The larger apertures may create an easier pathway for gas molecules to travel from MEMS stack 255 and other components into the region of emission tip 240 within upper gun chamber 213.

Finally, booster tube 230 may trap gas molecules within its volume, making it more difficult for ion pumps IP1 and IP2 to evacuate them from upper and lower gun chambers 213 and 214. For instance, outgassing molecules from MEMS stack 255 may pass through gun aperture 245 and into booster tube 230, where it may be prevented from passing into second ion pump IP2. Next, the outgassing molecules may pass through booster tube 230 and second aperture plate 242 to reach upper gun chamber 213. At least some of the outgassing molecules may further pass through first aperture 241 and adsorb to the surface of emission tip 240.

In view of the above problems, it may be desirable to provide a charged particle beam apparatus capable of being evacuated to an ultra-low pressure while maintaining high electron beam performance. For example, it may be desirable to provide a MEMS-based MBI tool that does not channel outgassing from a MEMS stack to an emission tip, yet still provides high voltage from a booster tube or the like.

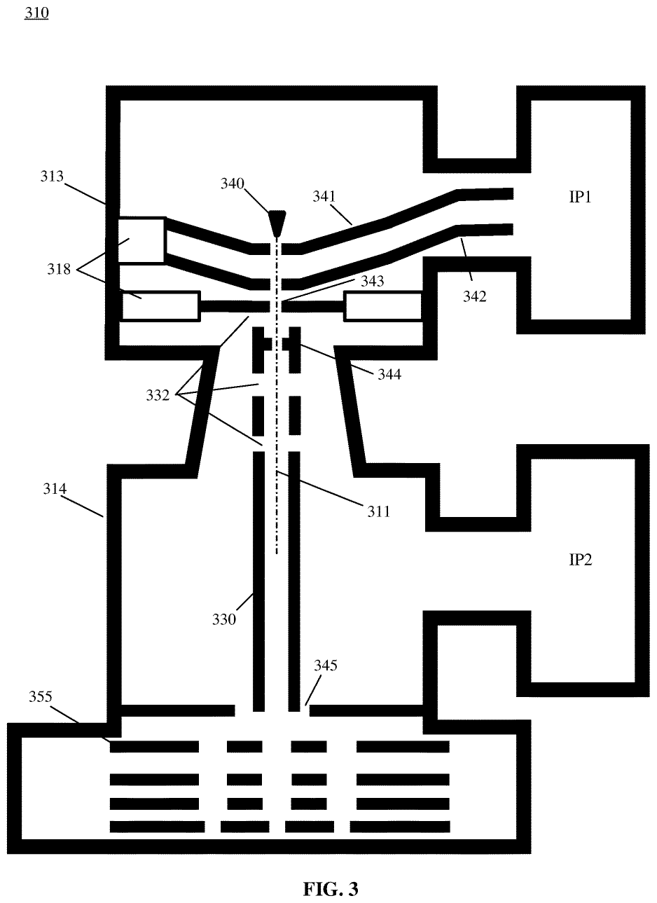

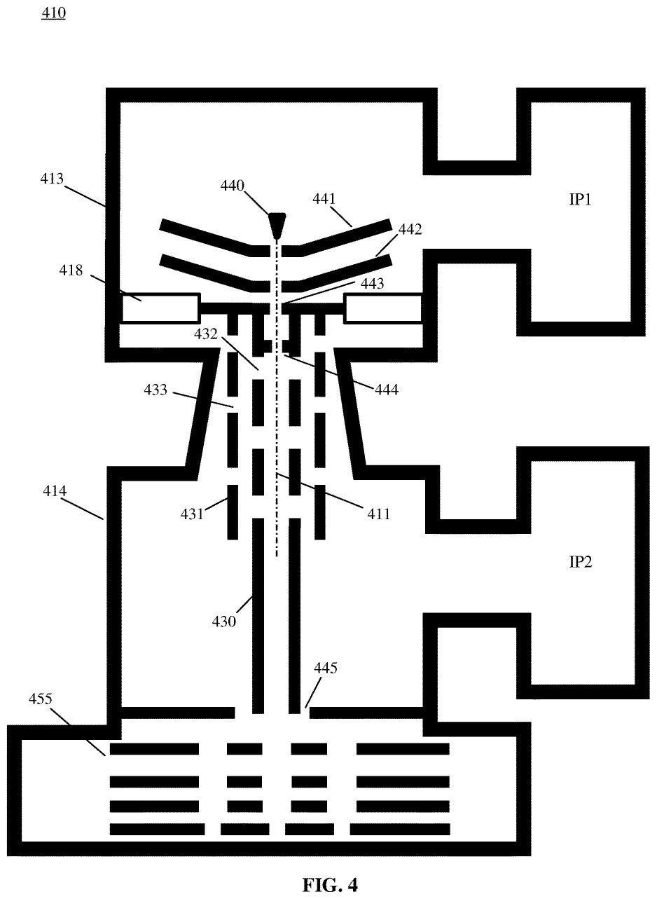

FIG. 3 illustrates an example electron beam source 310 and related components, consistent with embodiments of the present disclosure. Electron beam source 310 may be used in a charged particle system, such as EBI system 100 of FIG. 1A or electron beam tool 104 of FIG. 1B. Electron beam source 310 of FIG. 3 may be similar to, e.g., electron beam source 210 of FIG. 2 with the exception of the differences described below. Corresponding elements may be labeled with like numerals increased by 100, and their description may be omitted here. For instance, emission tip 340 of FIG. 3 may correspond to emission tip 240 of FIG. 2. The same may be true in further drawings below. For example, emission tip 440 of FIG. 4 may correspond to emission tips 240 of FIG. 2 or 340 of FIG. 3, etc.

In FIG. 3, electron beam source 310 may comprise a series of differential aperture plates 341-344 between emission tip 340 and gun aperture 345. For example, the series of differential aperture plates may comprise first aperture plate 341, second aperture plate 342, third aperture plate 343, and fourth aperture plate 344 arranged in series along the path of electron beam 311. In some embodiments, there may be more or fewer than the four differential aperture plates.

In some embodiments, there may be differential aperture plates on either side of a dividing aperture that divides upper and lower gun chambers 313 and 314. For example, first differential aperture plate 341 and second differential aperture plate 342 may be in located in upper gun chamber 313. Third differential aperture 343 may divide the upper and lower gun chambers 313 and 314. Finally, fourth differential aperture plate 344 may be located in lower gun chamber 314. In some embodiments, fourth differential aperture 344 may be located inside booster tube 330.

In some embodiments, one or more differential aperture plates may function as electrodes or other electron optics. For example, a power source (not shown) may be configured to apply a potential to one or more differential aperture plates 341-344. In some embodiments, first aperture plate 341 may be configured as an extractor and second aperture plate 342 may be configured as an anode, in a similar manner to aperture plates 241 and 242 of FIG. 2. In some embodiments, differential aperture plates may be formed of an electrically conductive material or other suitable electrode material. In some embodiments, differential aperture plates may be formed of an insulator another material that is not suitable for use as an electrode. As an example, in some embodiments, first different aperture plate 341 and third differential aperture 343 may be configured as electrodes and may be formed of, e.g., a metal. Second differential aperture plate 342 may be formed of a non-conductive material or another material designed to reduce its interference with the operation of the electrodes at first and third differential aperture plates 341 and 343.

In some embodiments a differential aperture plate may comprise a composite construction. For example, a central portion of a differential aperture plate may comprise a first material, and a peripheral portion may comprise second material. The first material may comprise a conductor, and the second material may comprise an insulator. In this way, an electric field may be generated only where it is desired to be generated. Yet the differential aperture itself may be as large as is necessary to prevent gas molecules from passing around an outer side of the differential aperture.

In some embodiments, the holes of differential aperture plates 341-344 may have substantially equal sizes. In some embodiments, the holes of differential aperture plates 341-344 may increase in diameter with increasing distance from emission tip 340. For example, the diameters may correspond to a cone-shaped profile of the spreading electron beam. In some embodiments, the holes of differential aperture plates 341-344 may decrease in diameter with increasing distance from emission tip 340, or may alternately increase and decrease. For example, the beam profile may converge on a crossover point along the path of differential aperture plates 341-344, and subsequently diverge downstream of the crossover point. In some embodiments the holes of differential aperture plates 341-344 may decrease in diameter as they approach a crossover point, and subsequently increase thereafter. In general, the arrangement of hole diameters in differential aperture plates 341-344 may be tailored to a particular charged particle beam design so that each differential aperture may be made as small as possible while still allowing sufficient electrons to pass. By providing a series of aperture plates, the likelihood of gas molecules passing to emission tip 340 may be reduced.

The differential aperture plates may be shaped and sized to guide gas molecules away from emission tip 340 and toward a vacuum pump. For example, at least one differential aperture plate may not be entirely planar, but may comprise a surface portion that is not perpendicular to an axis of electron beam 311. Stated another way, the surface portion may not be parallel to a line extending perpendicularly from the beam axis. In some embodiments, at least one differential aperture plate may be planar. For example, third differential aperture plate 343 may be planar, and while first and second differential aperture plates 341 and 342 may not be entirely planar. Further, a space between pairs of adjacent differential aperture plates may form a channel configured to guide gas molecules away from emission tip 340 and toward a vacuum pump, such as first ion pump IP1. For example, as seen at first and second differential aperture plates 341 and 342 in FIG. 3, the differential aperture plates may be larger than is necessary for performing electrode functions or beam-limiting functions. Instead, first and second differential aperture plates 341 and 342 may be large enough to extend to an inlet of first ion pump IP1 so that gas molecules passing through third aperture plate 343 may be safely pumped out of upper gun chamber 313. Further, the surface portions of adjacent differential aperture plates may not be parallel to each other. For example, the surface portions of two adjacent differential aperture plates may diverge from each other to create a channel width that increases with increasing distance from electron beam 311. This may allow gas molecules to enter the channel more easily than they can return to a region near emission tip 340.

Alternatively or additionally to the differential aperture system described above, electron beam source 310 may comprise a vented booster tube 330. For example, booster tube 330 may comprise a plurality of openings 332 along its sidewalls. Openings 332 may be spaced substantially equally along booster tube 330. Alternatively, openings 332 may be concentrated more densely at an upper or lower portion of booster tube 330. As seen in FIG. 3, openings 332 may be concentrated more densely near the boundary between upper and lower gun chambers 313 and 314. The vented booster tube 330 may allow gas molecules o escape and be pumped away by second ion pump IP2 before reaching upper gun chamber 313.

Openings 332 may be any desired shape or size. However, it may be desirable to surround electron beam 311 as much as possible with the electrode material of booster tube 330 to avoid unwanted effects on an electric field inside the tube in the region of electron beam 311. For example, booster tube 330 may be floating on high voltage such as, e.g., 30 kV. Meanwhile, the walls of upper or lower gun chambers 313 or 314 may be on ground potential. Therefore, a strong electric field may be present between booster tube 330 and the walls of upper or lower gun chambers 313 or 314. This strong e-field may extend into openings 332 and distort the e-field inside booster tube 330 if the size of openings 332 are too large. Peripheral electrons or peripheral beamlets within booster tube 330 may be particularly vulnerable to such disturbances, resulting in unwanted aberrations and beam shifts. On the other hand, if the openings are made too small, they will not achieve their intended function of providing a pathway for gas molecules to escape. Therefore in some embodiments, the size of openings 332 may be chosen to balance these competing parameters. For instance, the openings 332 may have a diameter of, e.g., 0.1 mm, 0.5 mm, 1 mm, 2 mm, 5 mm, 10 mm or more.

In some embodiments, the shape size, or relative placement of openings 332 may be arranged to minimize a disturbance of the e-field. For example, openings 332 may be shaped or arranged so that the harm caused by the e-field disturbance is minimized. In some embodiments, openings 332 may be distributed symmetrically about an axis of electron beam 311. In some embodiments, openings 332 may be arranged in proximity to an electrode capable of producing a compensating e-field. As shown in FIG. 3, openings 332 may be arranged close to third differential aperture 343 or fourth differential aperture 344. In such a case, third differential aperture 343 or fourth differential aperture 344 may be configured as a compensating electrode to offset a disturbance cause by the openings 332. Additionally, openings 332 may have complex shapes designed to minimize an e-field disturbance or control the form of such disturbance. Openings 332 may be, e.g., square, rectangular, slot shaped, star-shaped, etc. Openings 332 may comprise a plurality of pinholes. Openings 332 may comprise “cheese grater” type perforations with indentations that extend into or out of booster tube 330.

Furthermore, as described herein, the shape of booster tube 330 need not necessarily be cylindrical to be referred to as “tubular.” For instance, booster tube 330 may be cylindrical, however it may alternatively have a square, hexagonal, or diamond shaped cross-section, etc.

By providing differential aperture plates 341-344 or vented booster tube 330, low pressure and high cleanliness may be maintained at emission tip 340. Outgassed molecules from MEMS stack 355 may be divided into multiple flow branches and be pumped away by first and second ion pumps IP1 and IP2 more efficiently than in the comparative embodiment of FIG. 2. For example, pressure at emission tip 340 of FIG. 3 may be, e.g., 5 times lower than a pressure at tip 240 of FIG. 2.

When a booster tube comprises vented openings such as shown in FIG. 3, it may introduce problems with the electric field in the vicinity of electron beam 311 as discussed above. In some embodiments, further booster tube structures may be added to protect the e-field inside a booster tube while allowing gas molecules to escape.

FIG. 4 illustrates a further example electron beam source 410 and related components, consistent with embodiments of the present disclosure. Electron beam source 410 may be used in a charged particle system, such as EBI system 100 of FIG. 1A or electron beam tool 104 of FIG. 1B. In FIG. 4, openings 432 in a booster tube 430 may be covered as viewed in the radial direction perpendicular to an axis of electron beam 411. For example, electron beam source 410 may comprise two concentrically arranged booster tubes, an inner booster tube 430 and an outer booster tube 431. In some embodiments, more than two concentrically arranged booster tubes may be provided. Inner booster tube 430 may comprise first openings 432, and an outer booster tube 431 may comprise second openings 433. Outer booster tube 431 may be configured to cover openings 432 of inner booster tube 430 in the radial direction. For example, the inner openings 432 and outer openings 433 may be arranged so as to be offset in a radial direction perpendicular to the axis of electron beam 411. Stated another way, the inner openings 432 and outer openings 433 may be arranged so as not be aligned in a radial direction perpendicular to the axis of electron beam 411. In some embodiments, none of the first openings 432 are aligned with any of the second openings 433 in the radial direction. In this way, any electric fields generated between the high-voltage booster tubes 430/431 and the grounded walls of upper and lower gun chambers 413/414 may be prevented from extending into the interior of inner booster tube 430. In some embodiments, the intrusion of exterior electric fields into an interior of booster tube 430 may be reduced or eliminated. Yet gas molecules may still have a path to escape from the booster tubes and into, e.g, second ion pump IP2.

In some embodiments, the sizes of first openings 432 and second openings 433 may be substantially the same. For example, first openings 432 and second openings 433 may be similarly sized openings that are relatively rotated or axially shifted with respect to each other. In some embodiments, second openings 433 may be larger than first openings 432, or vice versa. For example, one of first and second openings 432/433 may be, e.g., 2 times, 5 times, or 10 times larger or more than the other of first and second openings 432/433. In this way, one set of openings may be optimized for producing a desired electric field and the other set of openings may be optimized for venting gas molecules. For example, inner booster tube 430 may comprise many relatively small openings 432 to allow gas to escape while substantially maintaining a desired electric field, and outer booster tube 431 may comprise few relatively large openings 432 to allow gas to escape freely. The smaller openings 432 may be arranged so as not to align radially with large openings 433.

In some embodiments, the length of inner booster tube 430 and outer booster tube 431 may be substantially equal. For instance, both inner booster tube 430 and outer booster tube 431 may extend through the full length of lower gun chamber 414. This may have the advantage of achieving a more uniform e-field over the length of booster tubes 430/431. In some embodiments, the length of inner booster tube 430 and outer booster tube may be different. For example, as shown in FIG. 4, outer tube 431 may extend over only a portion of inner booster tube 430, such as the portion comprising openings 432.

In some embodiments, a first voltage may be applied to inner booster tube 430 and a second voltage may be applied to outer booster tube 431. In some embodiments, the first voltage and the second voltage may be the same. For example, inner tube 430 and outer tube 431 may be coupled to the same power supply line, or they may otherwise be electrically coupled to each other. In some embodiments, inner booster tube 430 and outer booster tube 431 may be mechanically and electrically coupled to each other by, e.g., conductive mounting posts.

In some embodiments, the first and second voltages may be different. For example, the first voltage may be higher than the second voltage, or the second voltage may be higher than the first. In some embodiments, the first and second voltages may be independently adjustable. In some embodiments, inner booster tube 430 and outer booster tube 431 may be mechanically coupled to each other and electrically isolated from each other by, e.g., insulating mounting posts. In some embodiments, the first and second voltages may be chosen to achieve a desired net electric field in the vicinity of electron beam 411. For example, if the desired energy of electron beam 411 is 30 keV, then the first and second voltages applied to inner booster tube 430 and outer booster tube 431 may be chosen to yield a net e-field of 30 kV in the region of electron beam 411.

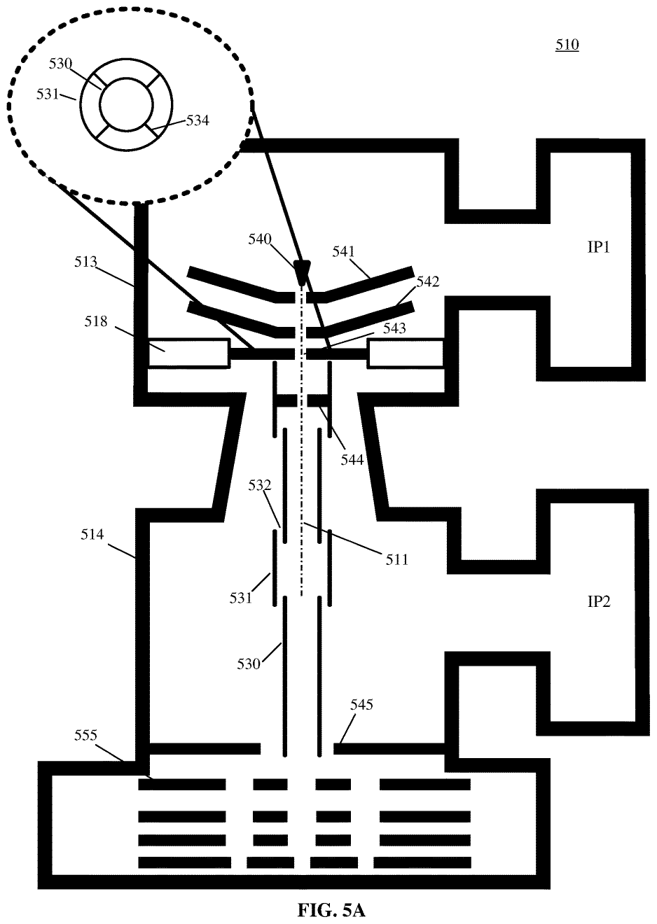

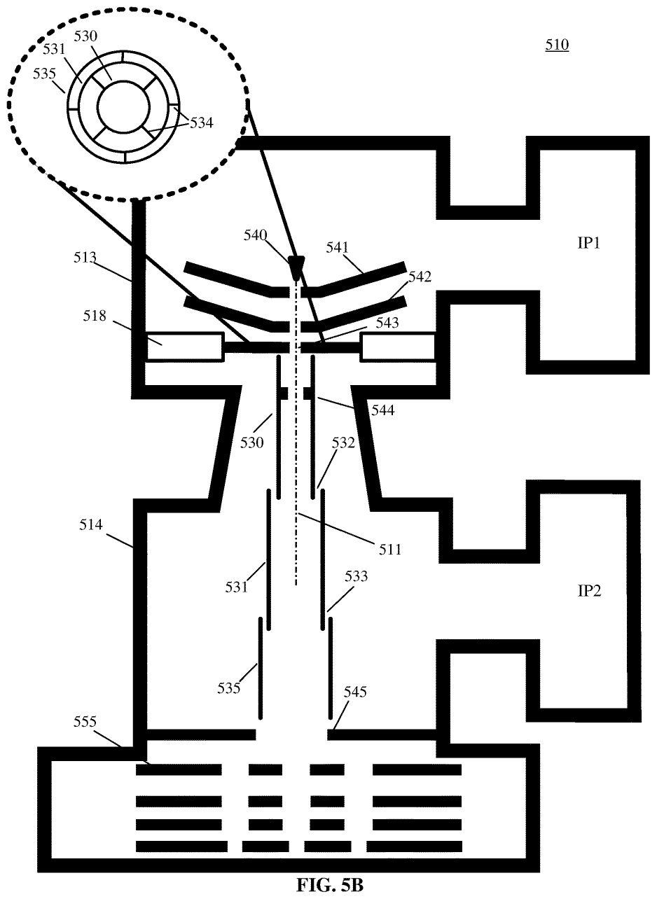

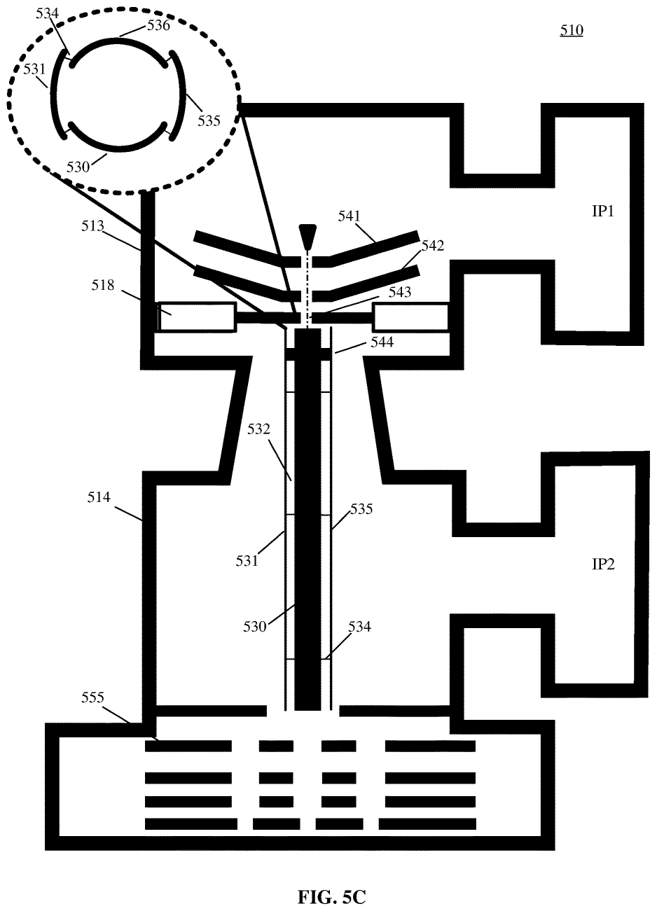

FIGS. 5A-C illustrate further examples of an electron beam source 510 and related components, consistent with embodiments of the present disclosure. Electron beam source 510 may be used in a charged particle system, such as EBI system 100 of FIG. 1A or electron beam tool 104 of FIG. 1B. Electron beam source 510 may comprise inner booster tube segments 530 and outer booster tube segments 531. Here, openings 532 may comprise annular gaps between inner booster tube segments 530 and outer booster tube segments 531. Inner and outer booster tube segments may be configured to overlap one another in the axial direction of electron beam 511 so as to cover openings 532 as viewed in the radial direction perpendicular to an axis of electron beam 511. In this way, gas molecules may be allowed to escape easily while the e-field inside the booster tube segments remains substantially undisturbed.

In some embodiments, similar to that discussed with respect to FIG. 4, the inner and outer booster tube segments may be held at the same potential. In some embodiments, the inner and outer booster tube segments may be held at slightly different potentials, for example to account for the differences in segment radius. In some embodiments, inner and outer booster tube segments may be separately supported. In some embodiments, as shown in the bird's-eye detail at the upper left corner of FIG. 5A (and similarly in FIGS. 5B-C), inner booster tube segments 530 may be mechanically coupled to outer booster tube segments 531 by, e.g., radial posts 534. In some embodiments, the radial posts 534 may comprise a conductive material to electrically couple the inner and outer booster tube segments 530/531. In some embodiments, the radial posts 534 may comprise an insulator to electrically isolate the inner and outer booster tube segments 530/531 from each other. In some embodiments, posts 534 may alternatively or additionally be arranged axially instead of radially. For example, each inner booster tube segment 530 may be coupled to the next by way of axial posts (not shown), and each outer booster tube segment 531 may be coupled to the next by way of further axial posts (not shown). Axial or radial posts 534 may allow for mechanical or electrical coupling without impeding the path of gas molecules toward, e.g., second ion pump IP2. In some embodiments as further discussed below, inner or outer booster tube segments 530 or 531 may be mechanically or electrically coupled by other mechanisms, such as a metal mesh.

FIG. 5B shows an alternative arrangement of booster tube segments, in which the booster tube segments may comprise continuously changing diameters. For instance, FIG. 5B shows a first booster tube segment 531, second booster tube segment 532, and third booster tube booster segment 535. The booster tube segments may comprise increasing diameters in a direction of travel of electron beam 511. Such arrangement may be advantageous, e.g., to accommodate an increasing width of electron beam 511 as it travels through lower gun chamber 514. Alternatively, the booster tube segments may comprise decreasing diameters in a direction of travel of electron beam 511. This may be advantageous as it avoids a funneling effect on gas molecules within the interior of the booster tube segments. For example, as gas molecules approach the third differential aperture 543 that divides upper and lower gun chambers 513 and 514, the gas molecules may spread farther away from the axis of electron beam 511 and therefore be more likely to escape to second ion pump IP2.

FIG. 5C shows an alternative arrangement of booster tube segments, in which the booster tube segments may comprise slat-like segments elongated in the axial direction of electron beam 511. For example as shown in FIG. 5C, there may be four elongated booster tube segments 530, 531, 535, and 536, however more or fewer than four may be used. The elongated booster tube segments may extend along a common length of an axis of electron beam 511. The elongated booster tube segments may overlap each other in the radial direction as shown in the bird's eye view at the upper left corner of FIG. 5C. In this way, axial gaps 532 may be covered as viewed in the radial direction perpendicular to the axis of electron beam 511. In some embodiments, the booster tube segments may be arranged at more than two radial distances from a central axis. For example, there may be three rows of elongated booster tube segments instead of the two rows shown in the upper-left corner of FIG. 5C, or the booster tube segments may be arranged in, e.g., a spiral shape as viewed from above.

Similar to FIGS. 5A and B above, elongated booster tube segments 530, 531, 535, and 536 may be coupled or isolated, either electrically or mechanically. For instance, in some embodiments, the elongated booster tube segments may be coupled by radial posts 534, which may comprise electrically conducting or electrically insulating materials. In this way, multiple gaps 532 may run along substantially an entire axis of electron beam 511 while maintaining a substantially uniform potential inside.

In FIGS. 5A-C, tubular booster tube segments are shown with substantially constant widths. However, this is not necessarily the case. For instance, in some embodiments the tubular booster tube segments or elongated booster tube segments may comprise flanged ends or other complimentary profiles designed to guide gas molecules out while preserving an internal e-field.

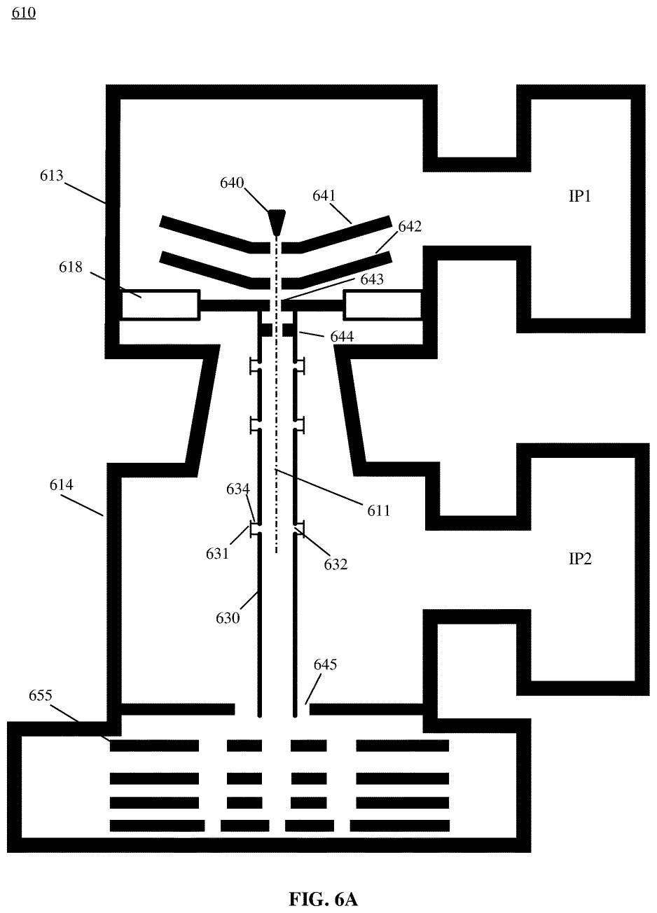

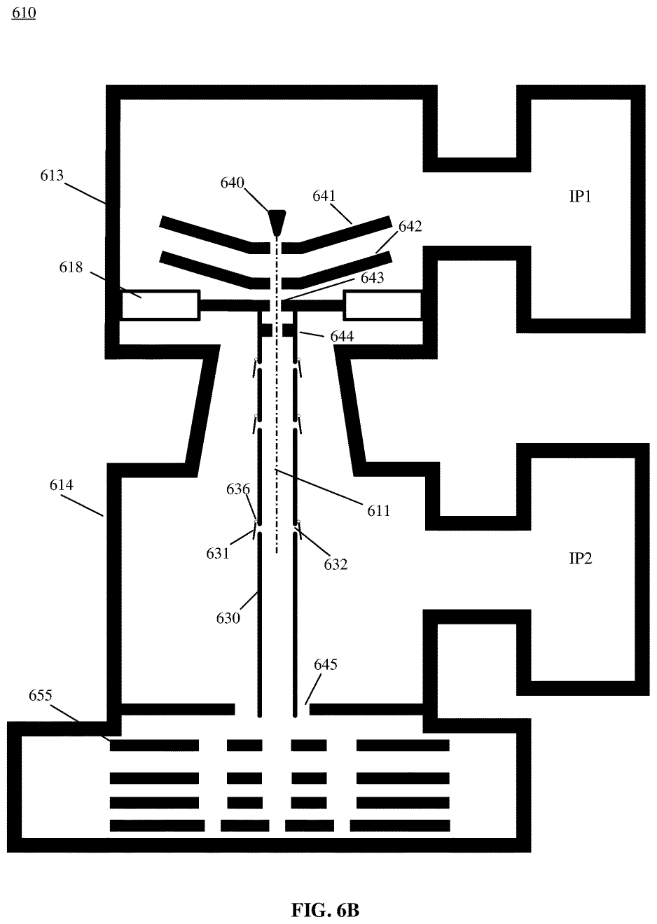

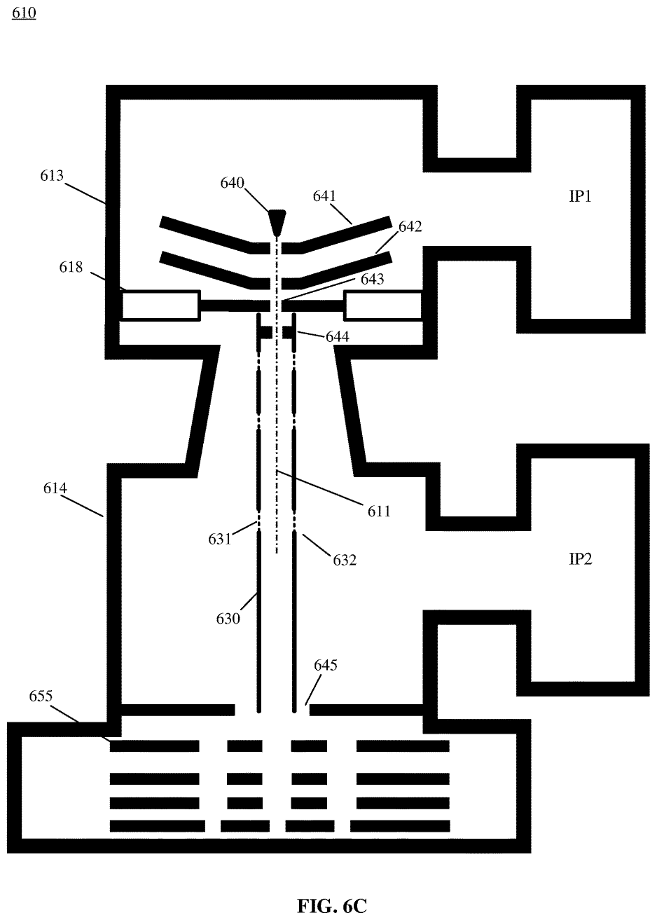

FIGS. 6A-B illustrate further examples of an electron beam source 610 and related components, consistent with embodiments of the present disclosure. Electron beam source 610 may be used in a charged particle system, such as EBI system 100 of FIG. 1A or electron beam tool 104 of FIG. 1B. In FIG. 6A, openings 632 in booster tube 630 may be covered by caps 631 instead of being surrounded by a full outer booster tube (such as outer booster tube 431 in FIG. 4). The caps 631 may be mounted to booster tube 630, such as by radial posts 634. For example, radial posts 634 and caps 631 may comprise a conductive material and be electrically coupled to booster tube 630. The arrangement of FIG. 6A may be advantageous in that booster tube 630 may very nearly correspond to a simple tubular electrode shape, similar to booster tube 330 of FIG. 3. Yet openings 632 may be covered to prevent external electric fields from protruding into the interior of booster tube 630.

FIG. 6B shows an alternative arrangement in which openings 632 may be covered by actuated caps 631. In some embodiments, caps 631 may be configured to rotate on hinges 636 to vary their opening amount depending on the state of electron beam source 610. For example, during an initial pump-down of upper and lower gun chambers 613 and 614, caps 631 may be fully opened to maximize a gas molecule flow path. However, during operation it may be desirable to cover openings 632. Thus, the caps may be rotated to partially or fully close during, e.g., an inspection operation. For example as seen in FIG. 6B, each cap 631 may be large enough to cover an entirety of its corresponding opening 632 even when the cap is rotated at some non-zero angle from the surface of booster tube 630. In this way, caps 631 may allow gas molecules to escape during operation of electron beam source 610. In some embodiments, caps 631 may be actuated to a fully closed position during operation so that they are in full contact with the surface of booster tube 630 to provide a superior e-field uniformity. In some embodiments, caps 631 may be configured to be substantially flush with the surface of booster tube 630 when in the closed position. While caps 631 are illustrated comprising hinges 636, any suitable actuation mechanism may be used. For example, caps 631 may slide along a surface of booster tube 630 to open or close, partially or fully. For instance, caps 631 may comprise an annular ring configured to slide up and down along booster tube 630.

FIG. 6C shows an alternative arrangement in which openings 632 may be covered by a permeable surface 631. For example, the permeable surface 631 may comprise a mesh electrode material. Alternatively, the permeable surface may comprise a porous material, a wire grid, etc. In general, the permeable surface may be contiguous with a surface of booster tube 630 to “fill” the openings 632. In some embodiments, permeable surface 631 and booster tube 620 may comprise the same material. In some embodiments, a thickness or other dimension of permeable surface 631 may be altered to compensate for any differences in strength between an electric field generated by booster tube 630 and an electric field generated by permeable surface 631. In some embodiments, permeable surfaces 631 may be arranged at an inside of booster tube 630 to compensate for any differences in the electric field strength. Therefore, while the permeable surface 631 may comprise holes that are directly exposed to the walls of lower gun chamber 614, such holes may be small enough (or the permeable surfaces may have suitable thickness, location, etc.) that a substantially uniform potential may be generated along with booster tube 630. For example, a mesh electrode 631 and solid booster tube 630 may be configured to generate a substantially continuous electric field when applied to a common power source. As a further example, permeable surface 631 may be formed of a different conductive material or a different alloy ratio to compensate for electric field differences. Therefore, permeable surface 631 may be said to “cover” openings 632 from external electric fields in the context of this disclosure.

FIG. 7 illustrates a further example of an electron beam source 710 and related components, consistent with embodiments of the present disclosure. Electron beam source 610 may be used in a charged particle system, such as EBI system 100 of FIG. 1A or electron beam tool 104 of FIG. 1B. In FIG. 7, all or most of booster tube 730 may comprise a permeable surface as discussed above with respect to FIG. 6C. In some embodiments, the permeable surface may comprise more than 50%, more than 75%, more than 90%, or all of the booster tube surface. For example, booster tube 730 may comprise a tubular mesh electrode having an array of small openings 732. A tubular mesh electrode may be advantageous because it may provide a large number of paths for gas molecules to escape from the interior of booster tube 730. The large availability of gas molecule paths may allow for openings 732 to be made much smaller than in other embodiments, even other permeable surface embodiments such as in FIG. 6C. For example, a tubular mesh electrode 730 as seen in FIG. 7 may allow a finer mesh size than would be feasible in, e.g., permeable surfaces 631 of FIG. 6C. Furthermore, because substantially the entire booster tube 730 may made from a single material type having a uniform radius, superior e-field uniformity may be achieved.

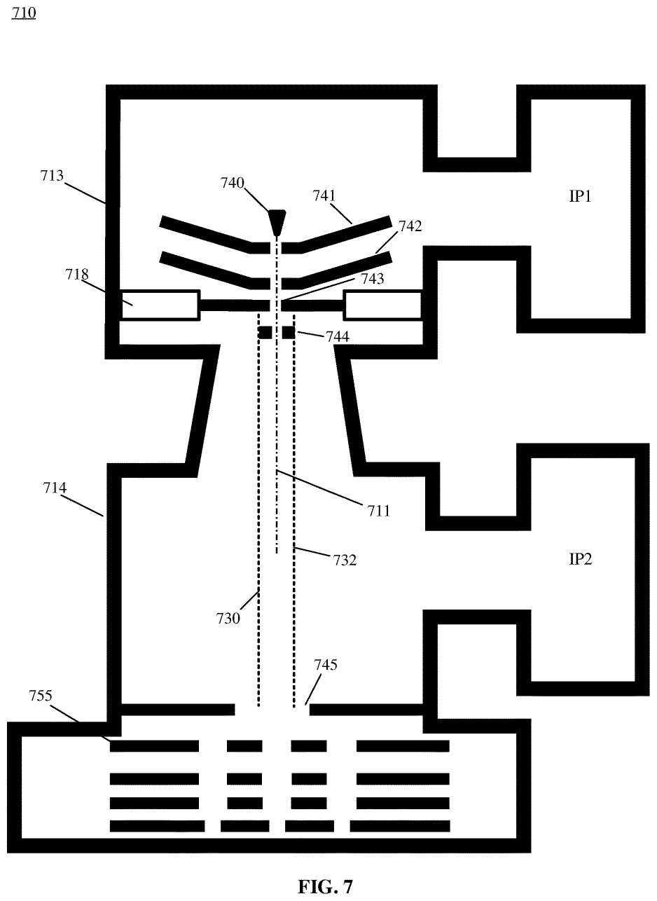

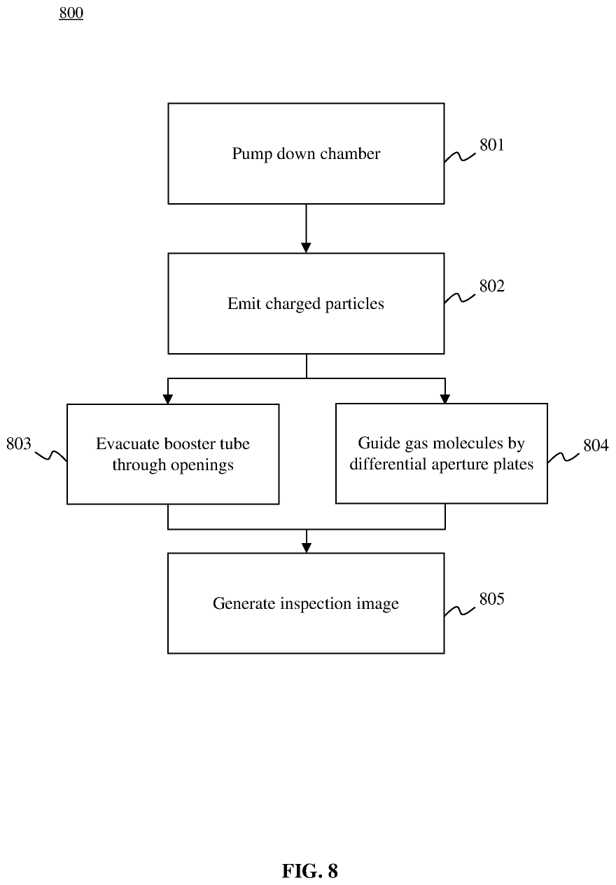

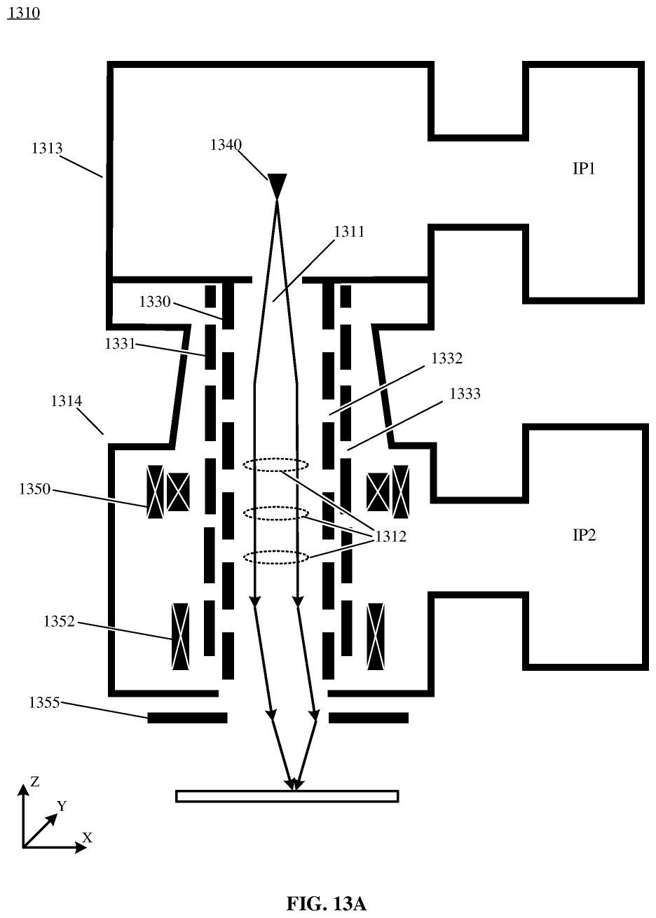

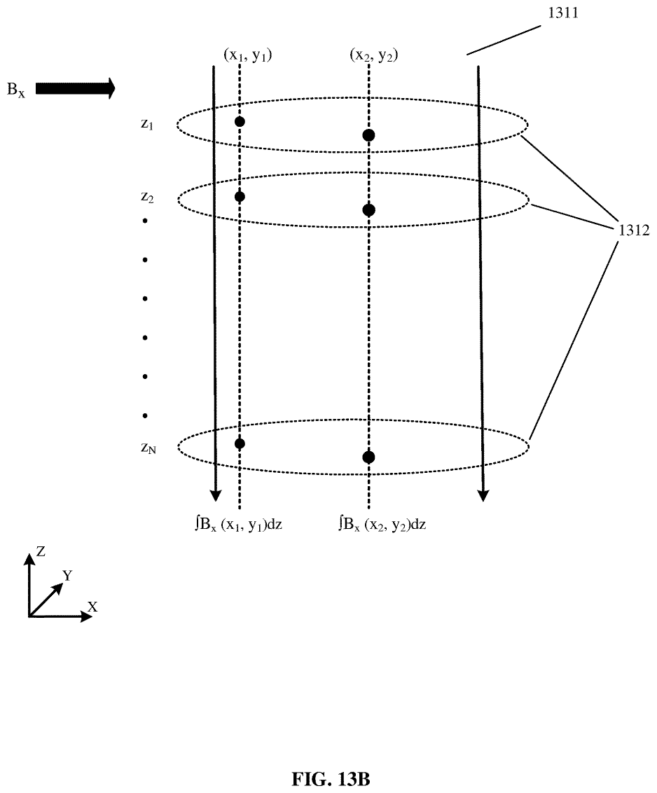

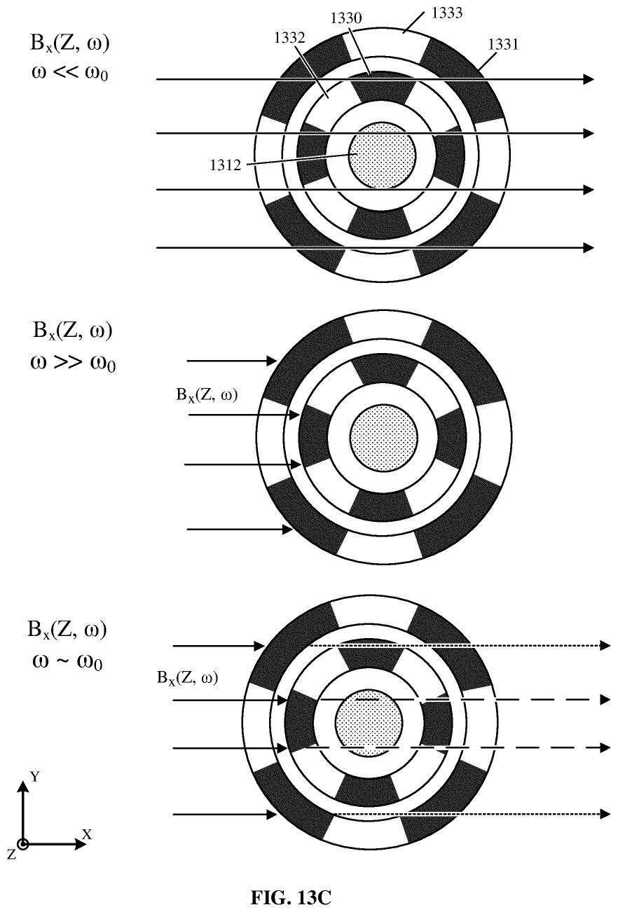

FIG. 8 is a flowchart illustrating an example charged particle beam generation method 800, consistent with embodiments of the present disclosure. Method 800 may be performed using a charged particle beam apparatus, such as EBI system 100 of FIG. 1A, beam tool 104 of FIG. 1B, or electron sources 310-710 of FIGS. 3-7 respectively. Furthermore, method 800 may be performed using electron source 1310 1310 of FIG. 13A-C described below, and comprising booster tube configurations as described with respect to FIGS. 13A-19B. The method may be performed by a controller (such as controller 109 in FIG. 1A). The steps given below in FIG. 8 are not necessarily performed in the order given. For example, some steps may be performed concurrently with others, or may be performed in earlier or later than the order presented. Further, not all steps are necessarily performed. For example, steps 803 and 804 may be performed together, or in the alternative.

At step 801, a chamber may be pumped down by a vacuum device. For example, the vacuum device may comprise ion pumps IP1 or IP2 of FIGS. 3-7, and the chamber may be, e.g., an upper gun chamber or a lower gun chamber. The chamber may be pumped to a high vacuum level in preparation for an electron beam operation, such as to a pressure lower than 1.0×10⁻¹¹ Torr. In some embodiments, the step 801 of pumping down the chamber may occur after a downtime such as during a routine maintenance period. In some embodiments, the step 801 of pumping down the chamber may comprise maintaining a vacuum level from a prior electron beam operation. At least one chamber may comprise a booster tube as discussed with respect to FIGS. 3-7 above.

At step 802, a charged particle emission source may emit charged particles. For example, the emission source may comprise an electron emission tip, such as a thermionic, Schottky, cold field or other electron emission tip. Electron emission may be initiated by heating, by generation of a strong electric field or both. In some embodiments, an extractor electrode may be configured to initiate electron emission from the emission tip. In some embodiments, an anode may be configured to accelerate the emitted electrons through an anode aperture to produce an electron beam. Further beam limiting apertures, lenses, coils, MEMS devices or other electron optics may also divide, shape, and guide the beam toward a sample such as a wafer.

At step 803, a booster tube may be evacuated by allowing gas molecules from inside the booster tube to pass through an opening in a sidewall of the booster tube. The opening may comprise holes, gaps, slits, perforations or separations between one portion of the booster tube and another. For example, the booster tube may be segmented, and the opening may comprise a gap between the booster tube segments. In some embodiments, the booster tube may comprise a permeable portion, or may be formed entirely, or in large part, of a permeable material such as a mesh electrode material. In general the booster tube may be structured in any suitable manner, including those according to any of the embodiments disclosed herein. The gas molecules passing out of booster tube may enter the vacuum device and may therefore be prevented from adsorbing to a surface of the emission tip.

At step 804, gas molecules may be guided away from an emission tip by a series of differential aperture plates. The differential aperture plates may be arranged along an axial direction of the electron beam. The differential aperture plates may be configured to operate as electrodes or other electron optics, such as the extractor or anode discussed above.

Differential aperture plates may create multiple paths for gas molecules to reach a vacuum device instead of the emission tip. Further, the differential aperture plates may create a series of obstacles for gas molecules to block them from reach the emission tip. While the differential aperture plates may serve other functions within thew electron beam source, such as beam limiting functions and electron optics functions, the apertures may be larger than is necessary to achieve such functions. For example, a differential aperture may extend to an inlet side of the vacuum device to guide gas molecules to the vacuum device. Some differential apertures may serve no other function than to block gas molecules or guide the gas molecules to a vacuum device. For example, a differential aperture may have a dimension, location, or configuration that does not function as an electrode, does not further limit the electron beam, etc. The differential aperture may be, e.g. arranged adjacent to another differential aperture plate to form a channel that guides the gas molecules to a vacuum device. In general, the differential aperture plates may be structured in any suitable manner, including according to any of the embodiments disclosed herein.

At step 805, the electron beam source may be used to generate an inspection image. For example, the electron beam may be incident on a sample surface such as a wafer, causing electrons (such as secondary electrons or backscattered electrons) to be emitted from the wafer surface. The emitted electrons may be detected at a detector (such as detector 120 of FIG. 1B), and the detections may be used to generate an inspection image. For example, the image may be generated using, e.g., image processing system 121 of FIG. 1B.

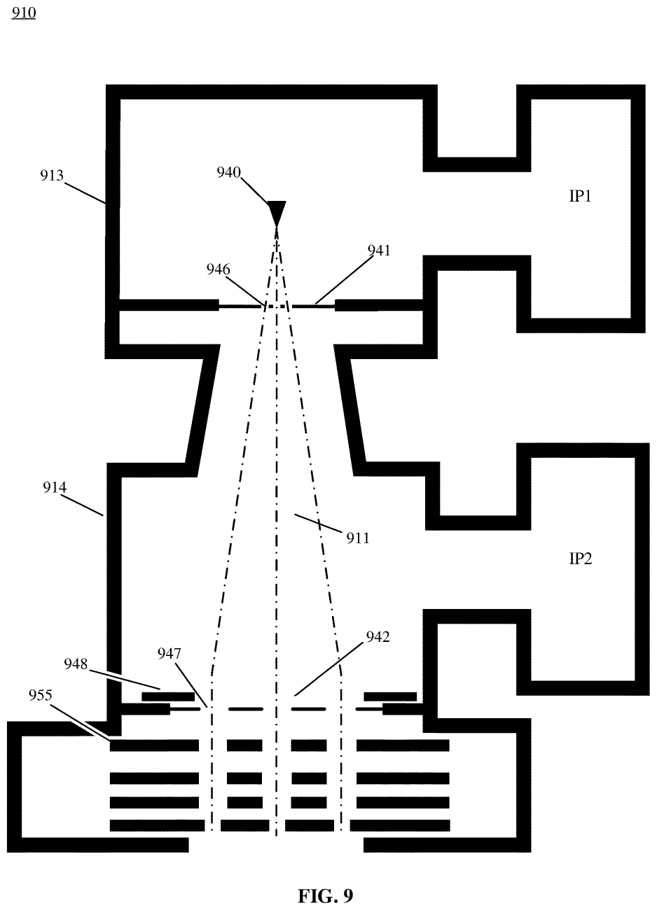

In some embodiments, an aperture may be located elsewhere within a charged particle beam apparatus to prevent unwanted gas molecules from reaching an emission tip, alternatively or in addition to the embodiments discussed above. FIG. 9 illustrates a further example electron beam source 910 and related components, consistent with embodiments of the present disclosure. Electron beam source 910 may be used in a charged particle system, such as EBI system 100 of FIG. 1A or electron beam tool 104 of FIG. 1B. As mentioned previously, while the system of FIG. 9 and others may be described in the context of an electron beam system, other charged particle or radiation beam systems are contemplated within the scope of the present disclosure.

Electron beam system 910 may comprise a first aperture plate 941 located downstream of emission tip 940. In some embodiments, the first aperture plate 941 may comprise one or more differential aperture plates as described above. For example, the first aperture plate 941 may be configured to substantially seal a region near emission tip 940 from a downstream region of upper or lower gun chamber 913 or 914, so that unwanted gas molecules may not pass to the region of emission tip 940 without passing through holes 946 of first aperture plate 941. First aperture plate 941 may, e.g., extend to or adjoin with a wall or other component of upper gun chamber 913 to block off alterative paths for the gas molecules.

In some embodiments, first aperture plate 941 may not be optimized specifically for preventing gas molecules from reaching emission tip 940. For example, first aperture plate 941 may be a coulomb aperture plate configured to block off peripheral electrons in an electron beam to reduce the coulomb effect. In some embodiments, coulomb aperture plate may help to define a size, shape, or number of beamlets 911. For example, the electron beam source 910 may be a multi-beam apparatus as illustrated in FIG. 9. First aperture plate may be, e.g., a 5×5 coulomb aperture array having a 5×5 array of holes 946. Holes 946 may be configured to block some electrons from emission tip 940. In some embodiments, electron beam source 910 may be a single-beam apparatus, and first aperture plate 941 may comprise a single hole 946. In general, first aperture plate 941 may comprise any suitable number and arrangement of holes corresponding to the number and arrangement of beamlets 941. In some embodiments, first aperture plate may function as both a coulomb aperture plate as well as a differential aperture plate configured to seal the region near emission tip 940. That is, the first aperture plate may be configured to limit the beam current and may also seal the region near emission tip 940 from downstream regions of upper or lower gun chambers 913 and 914.

Electron beam system 910 may comprise a second aperture plate 942 located downstream of first aperture plate 941. Second aperture plate 942 may be arranged between an outgassing source and a high-vacuum region. For example, second aperture plate 942 may be located at or near the exit between lower gun chamber 914 and a further component of a charged particle beam apparatus such as, e.g., MEMS stack 955. As discussed above, the outgassing source may comprise elements other than a MEMS stack 955. For example, the outgassing source may comprise a charged particle optical column or other charged particle optical device. In some comparative systems, the connection between lower gun chamber 914 and MEMS stack 955 may comprise a gate valve 948 or another relatively large opening that may allow large amounts of outgassing molecules into lower gun chamber 914. Second aperture plate 942 may instead be provided at or near this opening to seal the lower gun chamber from the outgassing source. For example, second aperture plate 942 may be configured so that gas molecules passing from the outgassing source may not enter lower gun chamber 914 except by passing through holes 947 of second aperture plate 942. All other paths may be blocked.

As discussed above, electron beam source 910 may be a multi-beam apparatus. Therefore second aperture plate 942 may comprise a single hole 947 or plurality of holes 947. In general, the number and arrangement of holes 947 may correspond to holes 946 of first aperture plate 941. However, the relative sizes, shapes, etc. may differ. For example, holes 946 of first aperture plate 941 may be sized to limit the beam current as discussed above, e.g., to define beamlets 911. Holes 947 of second aperture plate 942, on the other hand, may be large enough that they do not further limit the current of beamlets 911. Instead, second aperture plate 942 may be designed with the primary function of limiting the amount of gas molecules that enter lower chamber. For example, holes 947 may be made as small as possible without blocking electrons or otherwise adversely affecting the paths of beamlets 911.

In some embodiments, second aperture plate 942 may have a construction that reduces its influence on the paths of electrons in beamlets 911. Second aperture plate may be, e.g., formed of a non-conductive material. Second aperture plate may be, e.g., formed of a conductive material and maintained at an electric potential that corresponds to the potential of nearby components. This way, any disturbance to the local electric field by the presence of second aperture plate 942 may be minimized.

In some embodiments, second aperture plate 942 may be configured to influence the beamlet properties discussed above. For example, second aperture plate 1042 may be configured to function as an electrode or other electron optical element.

As discussed previously with respect to FIG. 1B, the outgassing source is illustrated as a MEMS stack 955. However, other components may be present alternatively or in addition to MEMS stack 955.

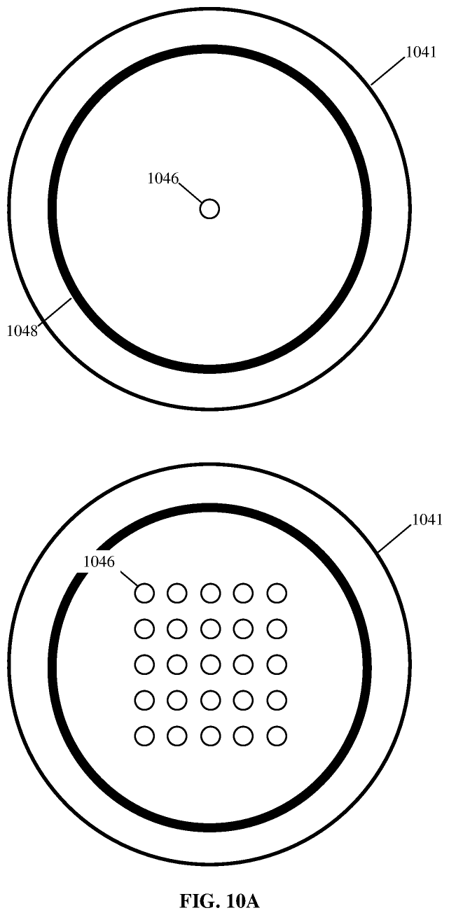

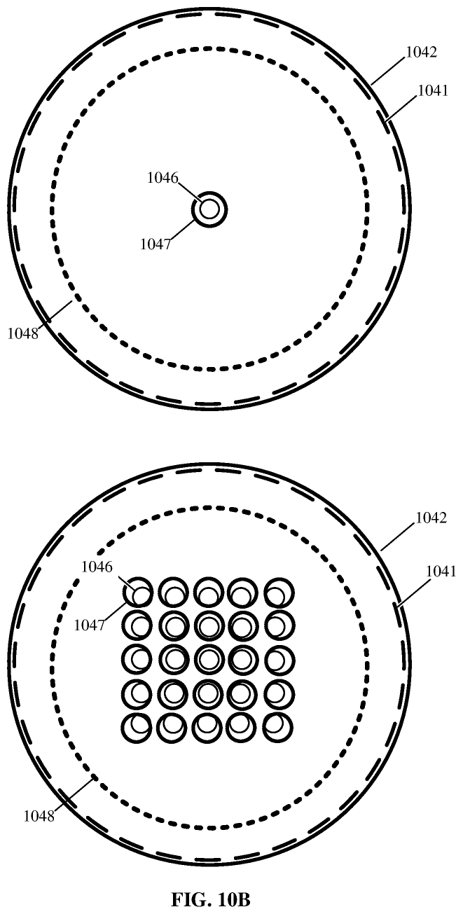

FIG. 10A schematically illustrates a view from a downstream side of a first aperture plate 1041 through a gate valve 1048, according to a comparative embodiment. In this view, a charged particle beam path (not shown) may be directed from aperture plate 1041, through gate valve 1048, and out of the page towards, e.g. an outgassing source (not shown). The outgassing source may be, e.g., a MEMS stack or other charged particle optical system similar to those discussed above. A single-beam embodiment is shown at the top of FIG. 10A, and 5×5 multi-beam arrangement is shown at the bottom.

In the comparative embodiment, gas molecules may escape from an outgassing source and travel through the relatively large opening of gate valve 1048 toward hole 1046 of first aperture plate 1041. Although some of those molecules may eventually be prevented from reaching an emission source, first aperture plate 1041 may not be optimized for the purpose of blocking such gas molecules. Further, contamination may be more effectively reduced by blocking gas molecules closer to their source. Therefore, at least a second aperture plate may be introduced.

FIG. 10B illustrates example configurations of a first and second aperture plate 1041 and 1042 of, e.g. system 910, consistent with embodiments of the present disclosure. Aperture plates of the type described in FIGS. 10A-B may be employed in combination with any embodiments of the present disclosure. In FIG. 10B, a second aperture plate 1042 is provided on, e.g., a downstream side of gate valve 1048. Further, a width of the opening of gate valve 1048 may be larger than a width of hole 1047 or the array of holes 1047. For example, in some embodiments, the width of gate valve 1048 may be 5, 10, 100, or 500 times the width of hole 1047 or of the array of holes 1047. Thus, first aperture plate 1041 and gate valve 1048 are illustrated in dashed lines to indicate that they are located behind second aperture plate 1042 from the viewpoint of FIG. 10B. In some embodiments, gate valve 1048 may be located in front of second aperture plate 1042 from the viewpoint of FIG. 10B. In general, second aperture plate may be located at an area that substantially prevents outgassing molecules from reaching the interior of a high-vacuum area, such as lower gun chamber 914 in FIG. 9.

Holes 1047 of second aperture plate 1042 may correspond to holes 1046 of first aperture plate 1041. Corresponding holes 1046 and 1047 may be configured to allow beamlets (not shown) from each hole 1046 to pass through their corresponding holes 1047 without being substantially affected by the second aperture plate 1042. For example, each of the holes 1047 may be substantially aligned with corresponding holes 1046 along their respective beamlet paths. Holes 1047 may be sized to allow the beamlets to pass without blocking electrons of the beamlets.

Second aperture plate 1042 may be configured to minimize its influence on the local electric field to avoid altering beamlet properties such as size, shape, energy, divergence or direction. For example, in some embodiments, second aperture plate 1042 may be formed of a non-conductive material. In some embodiments, second aperture plate 1042 may be formed of a conductive material. In some embodiments, the second aperture plate 1042 may be held at an electric potential corresponding to an electric potential of neighboring elements or a local field. For example, the electron beam source may comprise a component that is adjacent to second aperture plate 1042. The component may have an applied electric potential. The potential may be substantially constant in a time, or the component may have a time-varying potential. The second aperture plate 1042 may have an applied electric potential that is the same as, or similar to, the adjacent component.

As illustrated at the bottom of FIG. 10B, configuring the holes as “aligned along a beamlet path” may not always correspond to a rectilinear alignment, but may account for differing beamlet angles, deflections, etc. By way of example, a pair of aperture holes 1046/1047 at a center of the 5×5 array may be centrally aligned, while a pair of aperture holes 1046/1047 at a corner of the 5×5 array may not. Further, the hole sizes and shapes may not be constant across second aperture plate 1042, but may vary according to expected beamlet properties at the location of each hole 1047.

In some embodiments, aperture holes 1047 may be larger than aperture holes 1046. However, in some embodiments, the aperture holes 1047 may be equal to or smaller than aperture holes 1046. For example, as discussed above with respect to FIG. 3, a beamlet profile may converge on a crossover point along the beam path, and subsequently diverge downstream of the crossover point. Thus in some embodiments, holes 1047 of the second aperture plate may be smaller than holes 1046 of the first aperture plate, even when only the first aperture plate 1041 is configured to block electrons. It should further be understood that the hole arrangements and relative sizes of FIGS. 10A-B are depicted schematically for illustrative purposes only.

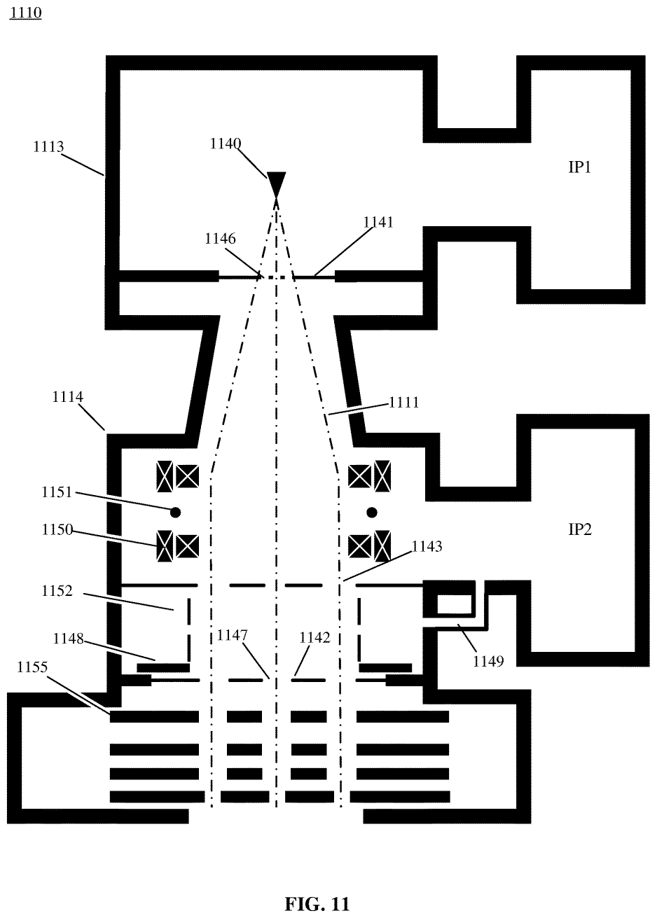

FIG. 11 illustrates a further example electron beam source 1110 and related components, consistent with embodiments of the present disclosure. Electron beam source 1110 may be used in a charged particle system, such as EBI system 100 of FIG. 1A or electron beam tool 104 of FIG. 1B. Electron beam source 1110 may be similar to, e.g. electron beam source 910 of FIG. 9.

Electron beam source 1110 may comprise a third aperture plate 1143, alternatively or in addition to second aperture plate 1142. Third aperture plate 1143 may be constructed according to the same design considerations as second aperture pate 1142, but may be provided at a different location, such as an intermediate region of lower gun chamber 1114. For example, third aperture plate 1143 may be inserted between charged particle optical elements in lower gun chamber 1114. As illustrated, third aperture plate 1143 may be located downstream of condenser lenses 1150 and cooling channels 1151, but upstream of deflectors 1152 and gate valve 1148. In some embodiments, third aperture plate 1143 or second aperture plate 1142 may have a static or time-varying electric potential applied. The electric potential may be the same as, or similar to, the electric potential of an adjacent or nearby component. For example, second aperture plate 1142 may have a potential that is similar to that of deflector 1152 or an upper layer of MEMS stack 1155. Third aperture plate 1143 may have a potential that is similar to that of condenser lens 1150 or deflector 1152.

By referring to an electric potential as “similar,” what is meant is that the potential applied to the aperture plate may not be perfectly equal to the potential applied to the adjacent component, but instead may be designed to maintain a desired electric field in a critical area, such as at the paths of beamlets 1111. For example, in view of differences in, e.g., location, geometry, or material composition between the aperture plate and the adjacent component, a small correction in their respective potentials may need to be applied. The desired result is that the aperture plate is configured to not disturb an electric field at the beam path that is generated by the adjacent component.

When provided as an alternative to second aperture plate 1142, third aperture plate 1143 may be beneficial, e.g., to accommodate space constraints in a particular beam source design, or to isolate further outgassing sources such as gate valve 1148. When provided as an additional aperture plate, third aperture plate 1143 may further disrupt the path of unwanted gas molecules between an outgassing source and emission tip 1140, similar to the series of differential aperture plates 341-344 discussed above with respect to FIG. 3. Electron beam source 1110 may comprise further aperture plates in series, for example a fourth, fifth, or sixth aperture plate (not shown). These additional aperture plates may have a design and arrangement as disclosed with respect to the illustrated second and third aperture plates 1042 and 1043.

Similarly to aperture plates 341-344, second aperture plate 1142 or third aperture plate 1143 may have surfaces configured to direct gas molecules toward a vacuum pump, such as second ion pump IP2. In some embodiments, spaces between second and third aperture plates 1142 and 1143 may be in fluid communication with second ion pump IP2, such as by an exhaust channel 1149. For example, exhaust channel 1149 may comprise a path from a space between the aperture plates to a vacuum pump, wherein the path does not include the holes of the aperture plates.

Further, it is noted that FIGS. 9-11 are depicted without the booster tubes of FIGS. 2-7. However, embodiments of the present disclosure are not limited to this. In some embodiments, systems of FIGS. 9-11 may comprise a booster tube according to any of FIGS. 2-7.

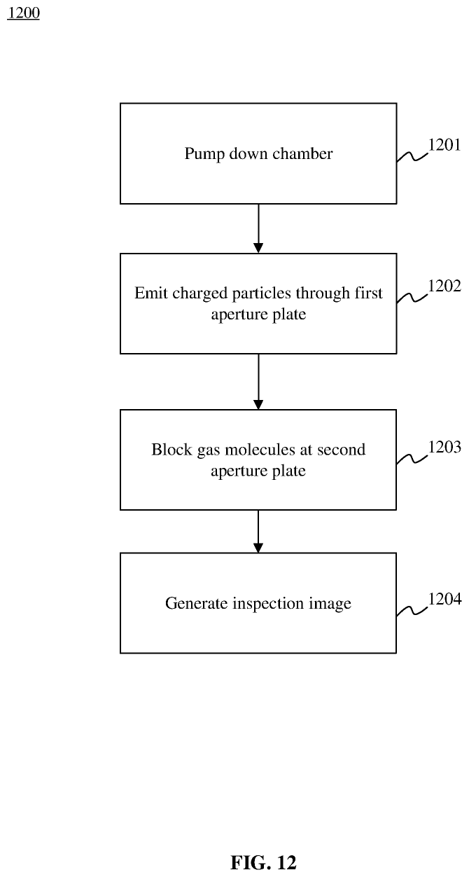

FIG. 12 is a flowchart illustrating an example charged particle beam generation method 1200, consistent with embodiments of the present disclosure. Method 1200 may be performed using a charged particle beam apparatus, such as EBI system 100 of FIG. 1A, beam tool 104 of FIG. 1B, or electron sources 910 or 1110 of FIGS. 9-11 respectively. The method may be performed by a controller (such as controller 109 in FIG. 1A). The steps given below in FIG. 12 are not necessarily performed in the order given. For example, some steps may be performed concurrently with others, or may be performed in earlier or later than the order presented.

At step 1201, a chamber may be pumped down by a vacuum device. For example, the vacuum device may comprise ion pumps IP1 or IP2 of FIGS. 9-11, and the chamber may be, e.g., an upper gun chamber or a lower gun chamber. The chamber may be pumped to a high vacuum level in preparation for an electron beam operation, such as to a pressure lower than 1.0×10⁻¹¹ Torr. In some embodiments, the step 1201 of pumping down the chamber may occur after a downtime such as during a routine maintenance period. In some embodiments, the step 1201 of pumping down the chamber may comprise maintaining a vacuum level from a prior electron beam operation. At least one chamber, or an area near an outlet of the chamber, may comprise a first aperture plate, as well as a second aperture plate or third aperture plate as discussed with respect to FIGS. 9-11 above.

At step 1202, a charged particle emission source may emit charged particles. For example, the emission source may comprise an electron emission tip, such as a thermionic, Schottky, cold field, or other electron emission tip. Electron emission may be initiated by heating, by generation of a strong electric field, or both. In some embodiments, an extractor electrode may be configured to initiate electron emission from the emission tip. In some embodiments, an anode may be configured to accelerate the emitted electrons through an anode aperture to produce an electron beam. Further beam limiting apertures, lenses, coils, MEMS devices or other electron optics may also divide, shape, and guide the beam toward a sample such as a wafer.

The charged particles may pass through at least one hole of a first aperture plate. Some charged particles may be blocked at the first aperture plate. For example, the first aperture plate may be a coulomb aperture plate configured to block off peripheral electrons in an electron beam to reduce the coulomb effect.

At step 1203, gas molecules may be blocked or guided away from an emission tip by a second aperture plate. The second aperture plate may be arranged at or near an area between a high vacuum chamber and a source of outgassing. For example, the second aperture plate may be arranged near a gate valve between a lower gun chamber and, e.g., a MEMS stack or other charged particle optical system. The second aperture plate may be configured to reduce the amount of gas molecules flowing into high vacuum chamber without substantially influencing a charged particle beam passing through holes of the second aperture plate. For example, the second aperture plate may have a hole that is large enough to allow substantially its entire corresponding charged particle beamlet pass without blocking charged particles. The second aperture plate may be formed of a material that is configured to reduce its influence on the local electric field, or may have an electric potential applied that corresponds to a local electric field.

At step 1204, the electron beam source may be used to generate an inspection image. For example, the electron beam may be incident on a sample surface such as a wafer, causing electrons (such as secondary electrons or backscattered electrons) to be emitted from the wafer surface. The emitted electrons may be detected at a detector (such as detector 120 of FIG. 1B), and the detections may be used to generate an inspection image. For example, the image may be generated using, e.g., image processing system 121 of FIG. 1B.

The problem of e-fields penetrating through the openings of a booster tube is discussed above with respect to FIGS. 3-8. A similar problem occurs with magnetic fields such as, e.g., applied electromagnetic (EM) fields from magnetic optical elements in an electron beam source. Openings in a booster tube can also allow EM fields to penetrate an electron beam path in spatially non-uniform ways, resulting in disturbances to the uniformity of the local EM field.

FIGS. 13A-C illustrate a further example electron beam source 1310 and related components, consistent with embodiments of the present disclosure. Electron beam source 1310 may be used in a charged particle system, such as EBI system 100 of FIG. 1A or electron beam tool 104 of FIG. 1B. Electron beam source 1310 may comprise an emission tip 1340 configured to emit electrons that may be formed into an electron beam 1311. A path of electron beam 1311 may pass through an inner booster tube 1330 and an outer booster tube 1331. Inner booster tube 1330 and outer booster tube 1331 may comprise openings 1332 and 1333, respectively, as discussed above with respect to FIGS. 3-8 and further discussed below. For example, openings 1332 and 1333 may comprise holes or slits in the sidewalls of inner booster tube 1330 and outer booster tube 1331, respectively. Inner booster tube 1330 and outer booster tube 1331 may comprise, e.g., non-ferromagnetic materials. Electron source 1310 may comprise one or more magnetic optical elements configured to manipulate the beam 1311 such as, e.g., a magnetic lens 1350 or a scanning AC magnetic deflector 1352. Such elements may generate EM fields that may penetrate inner booster tube 1330 or outer booster tube 1331, either at their walls or at the openings 1332 or 1333 (discussed further below with respect to FIG. 13C).

The degree of nonuniformity that results from these disturbances may be characterized by considering the variations in an integrated EM field Balong the electrons' trajectory. For example, in a scanning AC magnetic deflector, a magnetic dipole EM field Bₓ may be integrated along a z-direction of the beam path for each point (x, y) in the cross-sectional areas 1312 of the electron beam 1311 according to eqn. 1:

$$\int {B}_{x} ( x , y ) dz \qquad ( eqn . 1 )$$

For example, FIG. 13B schematically illustrates a close-up view of electron beam 1311 in the presence of an external EM field Bₓ. In some embodiments, the illustrated portion of electron beam 1311 may represent substantially the entire beam path along the length of a booster tube, such as inner tube 1330 or outer tube 1331 (not shown in FIG. 13B). In some embodiments, the illustrated portion of electron beam 1311 may represent a section of the beam path corresponding to a particular component of the electron beam source, such as magnetic lens 1350 or scanning AC magnetic deflector 1352 (shown in FIG. 13A). An EM field value at a first point (x₁, y₁) may comprise a summation of Bₓ values at the location (x₁, y₁) for each plane 1312 at z₁, z₂, . . . z_{N} along the path of electron beam 1311. Taking these discrete planes as infinitesimal values dz yields the integral shown at eqn. 1. A similar calculation may be used for the location (x₂, y₂) and other locations in an integrated x-y plane. The nonuniformity of electrons' physical status, such as acceleration, landing angle, landing position, may then be characterized by a metric that represents the variation of integrated EM field values across the integrated x-y plane. Note that the above calculations consider only axial motion of electrons in the z-direction, or assume that radial motions are negligible. However, it should be understood that radial motions of electrons in the x-y plane may also be considered in some embodiments of the present disclosure.

For example, as seen in FIG. 13A, high-frequency scanning magnetic AC deflector 1352 may deflect electrons by an angle ψ_{y}. The deflection angle ψ_{y} at each point (x, y) may be proportional to the integrated field such that ψ_{y} (x, y)∝∫Bₓ(x, y)dz. A nonuniformity of the deflection angle may be characterized by a nonuniformity of integrated EM field:

$$Nonuniformity = \frac{2 ( Max [ {ψ}_{y} ( x , y ) ] - Min [ {ψ}_{y} ( x , y ) ] )}{Max [ {ψ}_{y} ( x , y ) ] + Min [ {ψ}_{y} ( x , y ) ]} \qquad ( eqn . 2 )$$

Other magnetic optical elements, such as magnetic lens 1352, may generate similar non-uniformities.

In some embodiments, EM field Bₓ may comprise a static or time-varying magnetic field applied from an element such as, e.g., magnetic optical elements 1350 or 1352 of FIG. 13A, and the field may have a substantially uniform amplitude outside the booster tubes 1330 and 1331. However, due to differences in the type and amount of material traversed by the EM field Bₓ at different locations, the field may be attenuated by different amounts at different points (x, y, z) on the path of electron beam 1311. This attenuation may depend strongly on a relationship between the frequency ω of the EM field and the structural and material properties of the booster tubes 1330 and 1331.

For example, FIG. 13C illustrates a bird's eye view of inner and outer booster tubes 1330 and 1331 in the presence of EM field Bₓ for three different frequency ranges. The frequency ranges may correspond to ranges below, above, and near a skin depth frequency ω₀. The skin depth frequency ω₀ may comprise a frequency at which the skin depth of a booster tube is substantially equal to the booster tube's thickness. As is understood in the art, the skin depth may refer to the depth of a conductive material at which an EM field of a given frequency is reduced to e⁻¹, or approximately one third, of its initial amplitude. For instance, the formula for a skin depth d may be given as:

$$d = \sqrt{\frac{2}{μσω}} \qquad ( eqn . 3 )$$

where μ represents the permeability of the material, a represents the conductivity of the material, and ω represents the frequency of the EM field. Thus, a skin depth frequency ω₀ of a booster tube may be represented by:

$${ω}_{0} = \frac{2}{μσ {t}^{2}} \qquad ( eqn . 4 )$$

where μ represents the permeability of the booster tube material, σ represents the conductivity of the booster tube material, and t represents the thickness of the booster tube.

As seen at the top of FIG. 13C, at low frequencies where ω<<ω₀ the EM field may comprise a static (where ω=0) or quasi-static EM field. Under these conditions, the non-ferromagnetic booster tubes 1330 and 1331 may exhibit a very weak interaction with the external EM field Bₓ, thus allowing the field to pass through substantially undisturbed. On the other hand, at very high frequencies where ω>>ω₀ as seen at the middle of FIG. 13C, the booster tubes 1330 and 1331 may strongly attenuate the EM fields. In this case, most of the high-frequency EM field Bₓ may be absorbed at either the outer booster tube 1331 or inner booster tube 1330. In either case, the presence of openings 1332 or 1333 does not have a substantial impact on the nonuniformity of fields inside the booster tube. But for frequencies near a skin depth frequency ω₀, EM field Bₓ may be only partially attenuated. This may cause the field amplitude to vary significantly depending on the specific path a magnetic field line takes through the walls and openings of the inner and outer booster tubes 1330 and 1331. Thus there may be an unacceptable level of EM field nonuniformity in the vicinity of the electron beam.

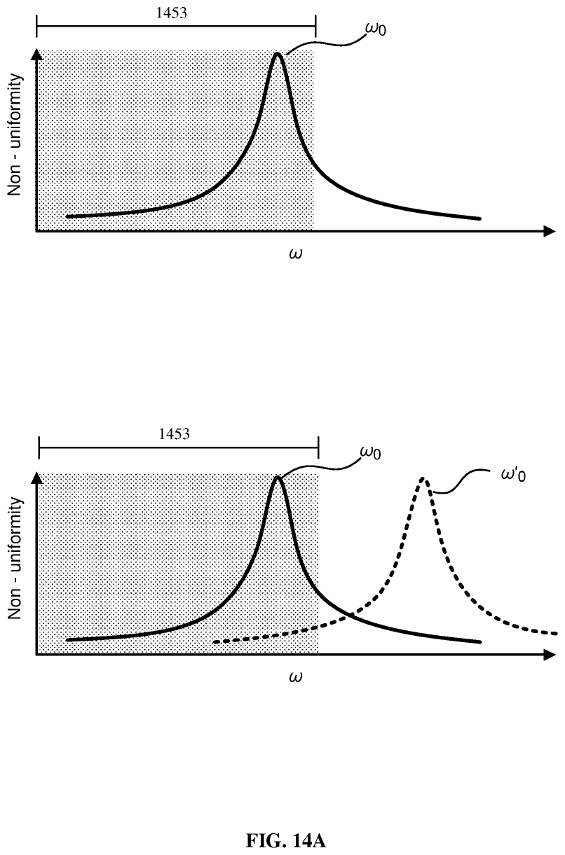

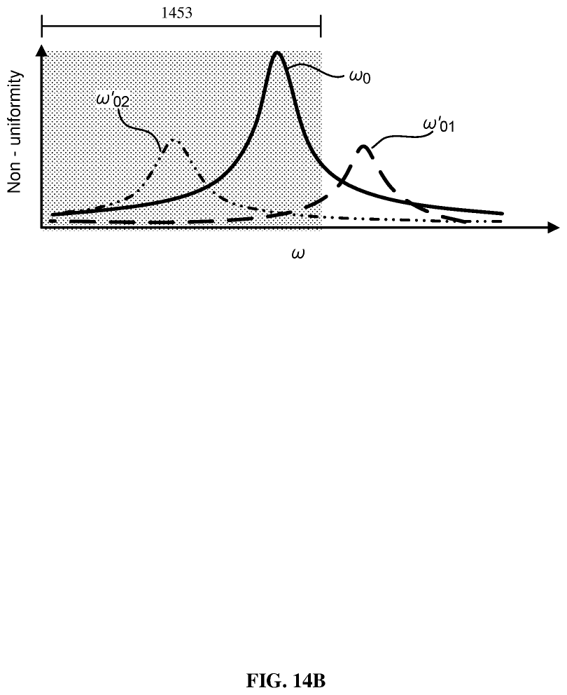

FIGS. 14A-B schematically illustrate this nonuniformity as a function of EM field frequency ω. As discussed above, and shown at the top of FIG. 14A, the EM field may be mostly transmitted at zero or low frequencies ω<<ω₀. Thus the non-uniformity may be relatively low because a magnetic field amplitude near an electron beam may be substantially the same regardless of what path a field line takes through inner or outer booster tubes (such as 1330 and 1331 of FIG. 13A) or their openings (such as 1332 and 1333 of FIG. 13A). Furthermore, at high frequencies ω>>ω₀, the EM field may be mostly attenuated. This results again in a low nonuniformity value because the field may be substantially absorbed before it reaches the electron beam. In the middle of these two ranges, a non-uniformity peak exists where frequencies ω are close to the skin depth frequency ω₀. A problem occurs if this nonuniformity peak, or a significant portion of it, occupies a working frequency bandwidth 1453 of a magnetic optical element or other component of the electron beam source.

Therefore, as shown at the bottom of FIG. 14A, in some embodiments a booster tube may be designed so that this nonuniformity peak is shifted away from a working frequency bandwidth 1453 of a component of the electron beam source. Such a design may be achieved by careful selection of the parameters discussed above with respect to egns. 3 and 4, such as the thickness t of the booster tube, or the conductivity σ or permeability μ of the booster tube material. According to eqn. 4, a decrease to any of t, σ or μ will increase the skin depth frequency to a higher value ω₀, thereby shifting the corresponding non-uniformity peak to the right in the graphs of FIG. 14A. For example, booster tube may be designed with a smaller thickness than would otherwise be used. In some embodiments, a booster tube may have a thickness t of, e.g., approximately 0.5 mm, 1 mm, 1.5 mm, or 2 mm. However, it may be difficult to manufacture booster tubes having extremely thin walls. Therefore, it may be desirable to achieve a skin depth frequency of ω′₀ by forming the booster tube from a material having a low conductivity. For example, in some embodiments an inner or outer booster tube may comprise Titanium, Chromium or alloys thereof.

In some embodiments, such parameters may be chosen so that a skin depth frequency ω′₀ is separated from the working frequency bandwidth 1453 by a large enough margin to effectively remove all of a nonuniformity peak from the working frequency bandwidth 1453. For example, in some embodiments, skin depth frequency ω′₀ may be separated from the upper limit of the working frequency bandwidth 1453 by 1, 1.5, 2, or 2.5 standard deviations of the non-uniformity peak. Alternatively or additionally, the booster tube parameters may be chosen so that a skin depth frequency ω′₀ is separated from the working frequency bandwidth 1453 by a full width at half maximum of the nonuniformity peak, or by another suitable measure to ensure that the non-uniformity is shifted away from the working frequency bandwidth.

In some cases it may not be feasible to shift the skin depth frequency ω₀ sufficiently above the working frequency bandwidth 1453. Therefore, in some embodiments, it may be desirable to split the skin depth frequencies of two or more booster tubes so that one large peak is converted into two or more smaller sub-peaks to reduce a maximum nonuniformity value. This technique is illustrated in FIG. 14B. A first booster tube may be designed with a first skin depth frequency ω′₀₁ that falls outside the working frequency bandwidth 1453, and a second booster tube may be designed with a second skin depth frequency ω′₀₂ that is shifted to the left to lie further inside the working frequency bandwidth 1453. For example, the first booster tube may comprise a first thickness, a first conductivity, or a first permeability. The second booster tube may comprise a second thickness, a second conductivity, or a second permeability. The first thickness, conductivity, or permeability may be smaller than the second thickness, conductivity, or permeability. The first booster tube may comprise one of an inner booster tube or an outer booster tube, and the second booster tube may comprise the other of the inner booster tube or outer booster tube. Additionally, more than two booster tubes may be present, and the nonuniformity peak may optionally be divided into more than two sub-peaks.

Using the techniques discussed above, a peak nonuniformity may be desirably relocated or divided to minimize its impact on the EM field at an electron beam path. However, there may be limits on the degree to which a skin depth frequency ω₀ can be adjusted. In some embodiments, superior uniformity may be achieved by configuring the booster tube openings so that variations at each location (x, y) in an EM field are averaged out along the z-direction.

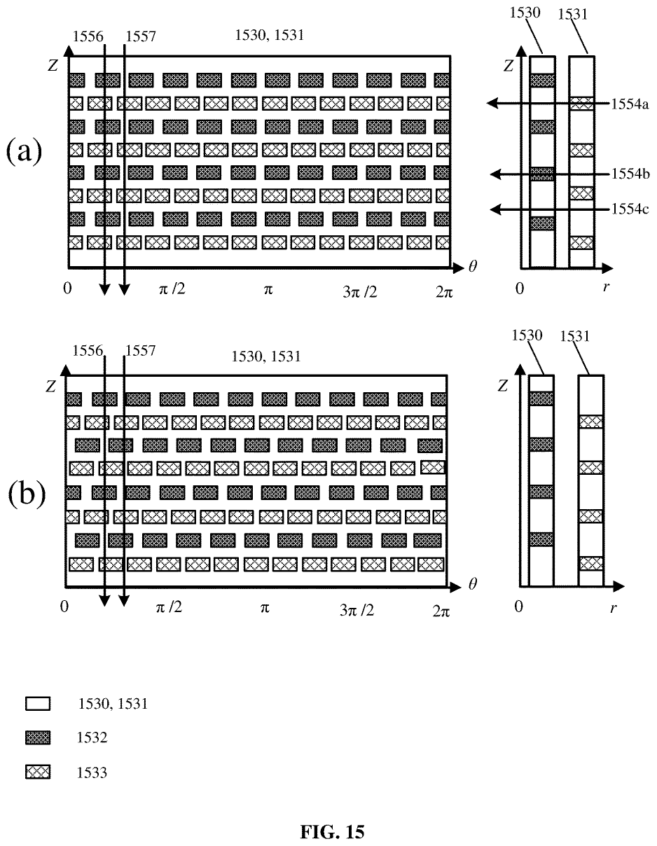

FIG. 15 schematically illustrates example booster tube opening arrangements (a) and (b), consistent with embodiments of the present disclosure. Each diagram (a) and (b) illustrates two schematic representations of a double booster tube arrangement having an inner booster tube 1530 and outer booster tube 1531. Dark patterned regions represent the locations of first inner openings 1532 in the inner booster tube 1530, while light patterned regions represent the locations of second outer openings 1533 in the outer booster tube 1531.

On the left, a first “unrolled” view shows the circular booster tubes depicted as flat rectangles, as if they were sliced along the z-direction, flattened and laid one on top of the other. The horizontal axes show an azimuthal angle θ of the tubes ranging from 0 to π, and the vertical axes show a z-direction corresponding to an electron beam axis (such as the vertical beam axis directions shown in, e.g., FIGS. 2-8 and 13A-B).

On the right, a second cross-sectional view shows the inner booster tube 1530 and outer booster tube 1531 in a radial direction r. The view of the right illustrates the different combinations of materials that an EM field line 1554 may encounter when crossing through the walls of inner booster tube 1530 and outer booster tube 1531. For example, the openings of each booster tube may be arranged in rows that are completely offset from each other in a z-direction. By “completely offset in a z-direction,” it is meant that a virtual line extending in a direction perpendicular to the z-direction through two adjacent wall portions of inner booster tube 1530 and outer booster tube 1531 cannot pass through both an inner opening 1532 and an outer opening 1533 in the two adjacent wall portions. This may allow for the openings to be made large while still providing a complete overlap of booster tube walls to ensure high electrostatic shielding. However, as a result, each field line 1554 may pass through at least one booster tube wall and be attenuated there. For example, a first EM field line 1554a may pass through outer opening 1533 and be attenuated at the wall of inner booster tube 1530. A second EM field line 1554b may be attenuated at the wall of outer booster tube 1531 but pass through an inner opening 1532. A third field line 1554c may be attenuated at both walls of inner booster tube 1530 and outer booster tube 1531. Each of these field lines may encounter different levels of attenuation, resulting in nonuniformities of the EM field in the region of an electron beam path. Further, the effects listed above represent only the simplest cases, and are presented only for illustrative purposes. In practice, nonuniformities can result from more complex interactions, such as when field lines enter a booster tube wall at non-normal incidence, through a lateral interior face of an opening, etc.

To minimize these nonuniformities, in some embodiments the openings may be arranged as shown on at the left side of FIG. 15. For instance, as seen at the top left, each row may be provided with a different number of openings to reduce the degree of azimuthal symmetry in attenuation profiles. Ideally, the number of openings should be large and should not introduce a low number of N-fold symmetry. For example, a first number of inner openings 1532 and a second number of outer openings 1533 may each be a different prime number to ensure that a low N-fold symmetry is not created. As illustrated in FIG. 15, the first number of inner openings 1532 is 11 and the second number of outer openings 1533 is 13. However, other prime numbers may be used. In some embodiments, non-prime numbers, such as odd numbers or large even numbers, may be used.

Furthermore, as shown at the bottom left in FIG. 15, rows of openings may be staggered in the azimuthal direction. For example, in some embodiments, each row of first openings 1532 may be azimuthally offset from a previous row of first openings 1532 by, e.g., one half period of the first openings 1532, or another suitable offset amount. The same may be true for rows of second openings 1533. This may serve to break any z-directional alignment of openings, resulting in a more uniform integrated EM field along any z-direction path. For example, FIG. 15 shows two identical pairs of z-directional paths 1556/1557 in both arrangement (a) and arrangement (b), respectively. The pairs may correspond to two z-directional paths through different (x, y) coordinates on a beam path (such as, e.g., coordinates (x₁, y₁) and (x₂, y₂) as seen in FIG. 13B). In arrangement (a), because there is no offset between rows of openings 1532 or 1533, each of the paths 1556 and 1557 may experience different repeating cycles of openings and solid walls along the z-direction. For example, first z-directional path 1556 may pass in front of four first openings 1532 and four second openings 1533. Meanwhile, second z-directional path 1557 may pass in front of zero first openings 1532 and four second openings 1533. As a result, the two paths may be exposed to very different EM field values, even when integrated along the full z-directional path. Therefore, the difference in integrated EM fields between the first and second z-directional paths 1556 and 1557 may be large. Instead, as shown in arrangement (b), each successive row of openings in the first and second booster tubes 1530 and 1531 is offset in the azimuthal direction by a prescribed amount, so that the integrated EM fields of z-directional paths 1556 and 1557 are much more similar.

It should be noted that the description in the preceding paragraph is simplified for illustrative purposes. Each of the paths 1556 and 1557 is surrounded by all of the openings 1532 and 1533. Nevertheless, for a given EM field direction, the description above illustrates how different (x, y) coordinates can experience different integrated EM fields, and how these differences can be smoothed out or otherwise mitigated by staggering the rows of openings. It should be noted that in some embodiments, these staggered offsets need not be arranged in increments of one half period. For example, each row could advance by, e.g, one fifth of a period, and the sequence would repeat every five rows. Additionally, the staggering need not occur in sequential order. Furthermore, aside from staggering the openings, other arrangements may provide similar smoothing effects. For example, the rows of first openings 1532 need not all contain the same number, size, or shape of openings, and the same may apply to rows of second openings 1533. In general, any of an offset, number, size, duty cycle (ratio of wall area to opening area in the direction of repetition), or other parameter of the openings may be varied in each booster tube to make the integrated EM fields along different z-directional paths more uniform.

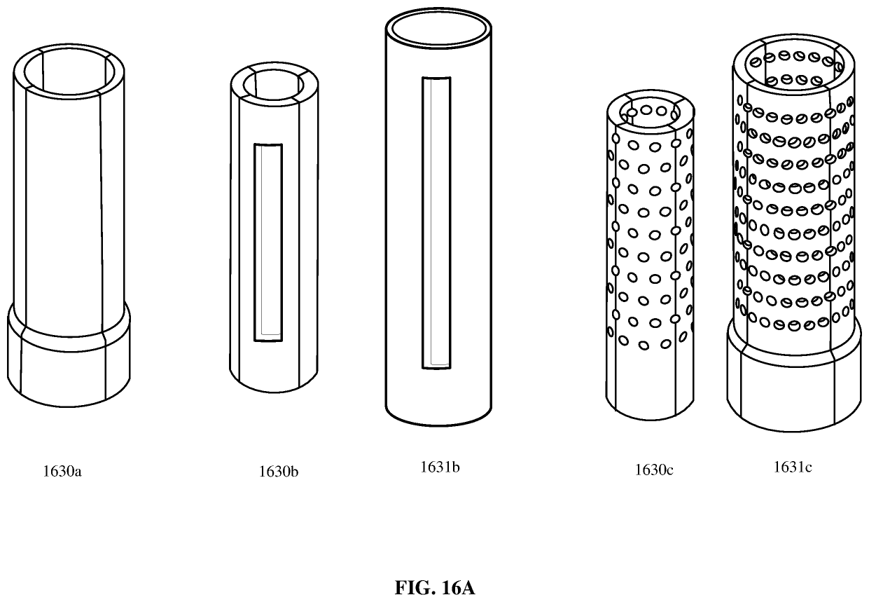

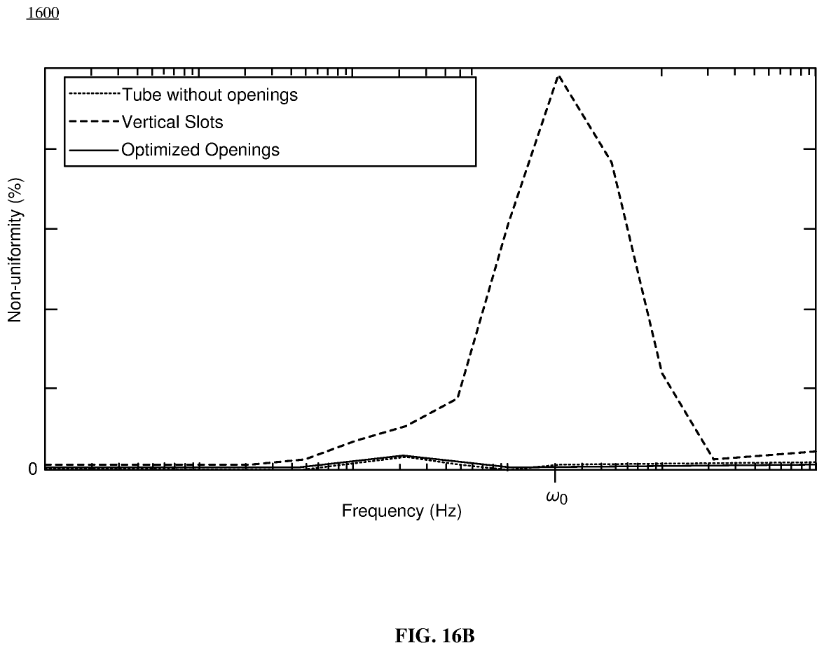

FIGS. 16A-B illustrate three booster tube configurations and an example chart 1600 plotting non-uniformity as a function EM frequency for each. The three configurations are: a solid booster tube 1630a (similar to, e.g., the configuration seen in FIG. 2); a dual booster tube configuration having inner booster tube 1630b and outer booster tube 1631b, each with elongated slots along the z-direction (similar to, e.g., the configuration seen in FIG. 5C); and an optimized configuration according to FIGS. 13A-15, having inner booster tube 1630c and outer booster tube 1631c. In some embodiments, booster tubes 1630 and 1631 of the optimized configuration may comprise a skin depth frequency ω₀ that lies outside a working frequency bandwidth of electron beam source elements, as shown in FIG. 14A. In some embodiments, booster tubes 1630 and 1631 of the optimized configuration may comprise rows of openings that alternate with each other in the z-direction. Further, each of inner booster tube 1630c and outer booster tube 1631c may comprise openings that are staggered azimuthally as shown in arrangement (b) of FIG. 15.

As far as EM nonuniformity is concerned, booster tube 1630 having no side openings can be considered the ideal case, as seen in chart 1600 of FIG. 16B. But as discussed above, vacuum pumping efficiency may be poor. Meanwhile, the vertical slot configuration 1630b and 1631b may have good vacuum pumping efficiency and may perform well in some frequency ranges. But it may exhibit a large nonuniformity peak in the vicinity of a skin depth frequency ω₀. In contrast to these, the optimized arrangement has superior vacuum pumping efficiency and exhibits a nonuniformity profile that very nearly matches the ideal case of the solid booster tube.

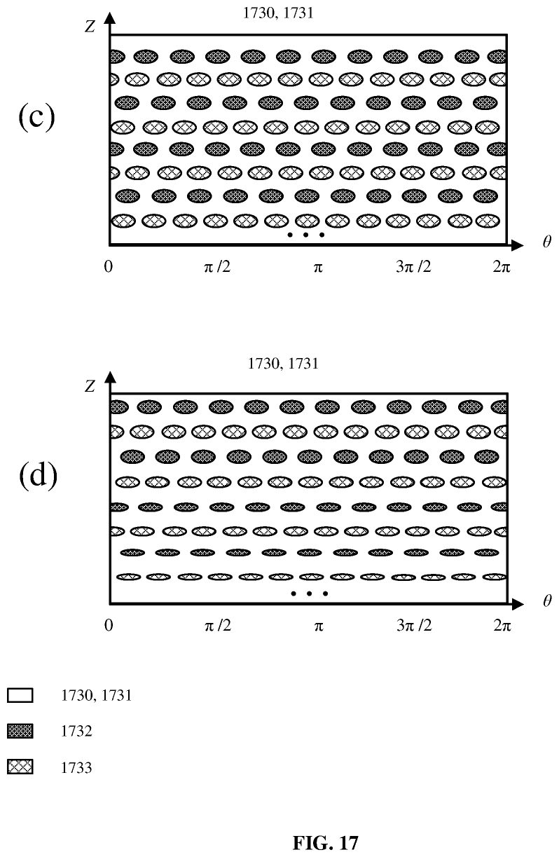

In some embodiments, further modifications may be made to the booster tube configurations discussed above. For example, while the openings 1532 and 1533 in FIG. 15 were illustrated as rectangular, this is not necessarily the case. In general the openings may take any shape. FIG. 17 illustrates schematically illustrates example booster tube opening arrangements (c) and (d), consistent with embodiments of the present disclosure. In FIG. 17, inner booster tubes 1730 and outer booster tubes 1731 may comprise an elliptical shape, such as a circular or oval shape. Such contours may be simpler to manufacture, or may allow for manufacture of larger openings or thinner tubes than would be possible with rectangular openings. Further, using elliptical openings may reduce the risk of producing sharp edges or other imperfections that may lead to unwanted variations in hole size or create a risk of arcing.

Additionally, as seen in arrangement (c), openings may have sizes that vary according to a changing strength of an EM field. For example, some EM fields may vary in the z-direction. Changing the size of openings changes the ratio of hole to solid wall, and therefore the attenuation rate of an EM field. Therefore, in some embodiments, the hole sizes may be tailored according to an expected EM field profile. For instance, if an EM field gets larger in the negative z-direction, openings may be made smaller in the negative z-direction to compensate this change.

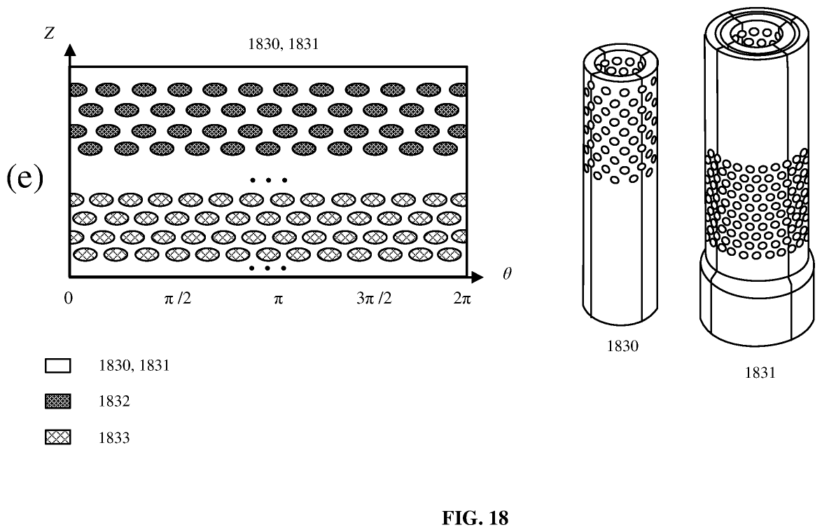

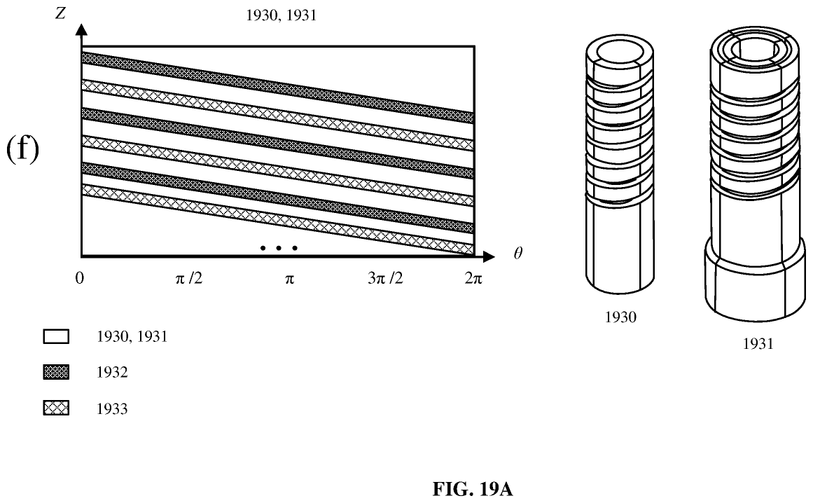

Additionally, as shown in FIG. 18, the openings of inner and outer booster tubes need not alternate between individual rows in the z-direction, but may take other non-overlapping arrangements. For example, in FIG. 18, an example booster tube opening arrangement (e) concentrates all inner booster tube openings 1832 in a first region in the z-direction and all outer booster tube openings 1833 in a second region in the z-direction. Alternatively, openings 1832 and 1833 may alternate in sets of two rows, three rows, etc., or may alternate with more complex patterns or irregular numbers of rows. In general, the inner and outer booster tube openings may be arranged so that they do not overlap each other in an electron beam axis direction. In any such arrangement, the openings 1832 and 1833 may be staggered in a similar manner as shown in arrangement (b) of FIG. 15 to achieve substantially similar effects.

Furthermore, in some embodiments the openings may take forms other than discrete holes.

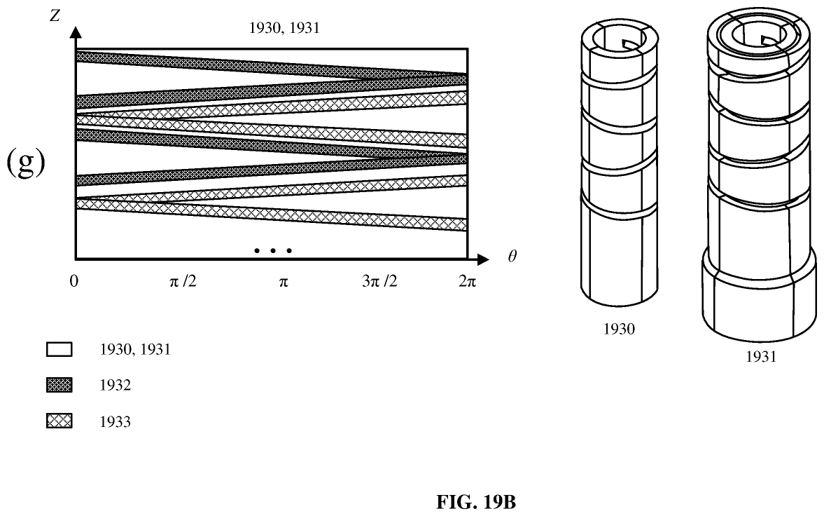

For example, as shown in FIGS. 19A-B, openings 1932 and 1933 of inner and outer booster tubes 1930 and 1931 may take the form of elongated slits that wrap around the tubes to create non-overlapping openings. For instance, as shown in FIG. 19A, inner booster tube openings 1932 and outer booster tube openings 1933 may comprise one or more spiral slits. As shown in FIG. 19B, inner booster tube openings 1932 and outer booster tube openings 1933 may comprise one or more zig-zag slits. Designs according to FIGS. 19A-B may achieve high vacuum efficiency by providing large extended paths for gas molecules to escape from a the booster tube interiors.

The embodiments of the present disclosure may further be described using the following clauses:
1. An apparatus, comprising:
   a vacuum chamber;
   a source located inside the vacuum chamber and configured to emit charged particles;
   an electrode configured to accelerate the charged particles to generate a charged particle beam; and
   a booster tube configured to surround the charged particle beam within the vacuum chamber and generate a uniform potential inside the booster tube, the booster tube comprising an opening configured to allow gas molecules from inside the booster tube to pass to a region outside the booster tube, the region being adjacent to the booster tube in a radial direction perpendicular to an axis of the charged particle beam.
2. The apparatus of clause 1, wherein the opening comprises a hole in a sidewall of the booster tube.
3. The apparatus of clause 1, wherein the booster tube comprises a first booster tube segment and a second booster tube segment; and
   the opening comprises a gap between the first booster tube segment and the second booster tube segment.
4. The apparatus of clause 3, wherein the first booster tube segment and the second booster tube segment comprise tubular booster tube segments configured to substantially surround a portion of the charged particle beam.
5. The apparatus of clause 4, wherein the first booster tube segment has a different diameter than the second booster tube segment.
6. The apparatus of clause 3, wherein the first booster tube segment and the second booster tube segment comprise elongated booster tube segments that extend along a common length of the charged particle beam.
7. The apparatus of clause 3, wherein the first booster tube segment and the second booster tube segment are configured to overlap in the radial direction perpendicular to the axis of the charged particle beam.
8. The apparatus of clause 3, wherein the first booster tube segment and the second booster tube segment are configured to be held at a same electric potential.
9. The apparatus of clause 3, wherein the first booster tube segment and the second booster tube segment are configured to be held at a different electric potential.
10. The apparatus of clause 1, wherein the opening comprises a permeable surface.
11. The apparatus of clause 10, wherein the permeable surface comprises more than half of the booster tube surface.
12. The apparatus of clause 1, wherein the booster tube comprises a cover, the cover being configured to reduce an intrusion of an exterior electric field into an interior of the booster tube through the opening.
13. The apparatus of clause 12, wherein the cover comprises a second booster tube surrounding the booster tube.
14. The apparatus of clause 13, wherein the second booster tube comprises a second opening configured to allow gas molecules from inside the second booster tube to pass outside the second booster tube.
15. The apparatus of clause 14, wherein the opening and the second opening do not overlap in the radial direction perpendicular to the axis of the charged particle beam, such that all lines emanating in the radial direction from the charged particle beam pass through a wall of at least one of the first tube and the second tube.
16. The apparatus of clause 12, wherein the cover comprises a plurality of booster tube segments configured to overlap each other in the radial direction perpendicular to the axis of the charged particle beam.
17. The apparatus of clause 12, wherein the cover comprises a cap spaced apart from the booster tube.
18. The apparatus of clause 12, wherein the cover comprises a cap configured to be actuated between an open and closed position over the opening.
19. The apparatus of clause 12, wherein the cover comprises a permeable surface.
20. The apparatus of clause 19, wherein the permeable surface comprises a mesh electrode.
21. The apparatus of clause 1, further comprising a plurality of differential aperture plates configured to pass the charged particle beam.
22. The apparatus of clause 21, wherein the plurality of differential aperture plates is configured to guide gas molecules to the vacuum pump.
23. The apparatus of clause 21, wherein the plurality of differential aperture plates is arranged along an axial direction of the charged particle beam, each differential aperture plate comprising a hole,
   wherein a size of the holes of each differential aperture plate of the plurality of differential aperture plates increases with increasing distance from the source.
24. The apparatus of clause 21, wherein a differential aperture plate of the plurality of differential aperture plates is located inside the booster tube.
25. An apparatus, comprising:
   a vacuum chamber;
   a vacuum pump;
   a source located inside the vacuum chamber and configured to emit charged particles;
   an electrode configured to accelerate the charged particles to generate a charged particle beam; and
   a plurality of differential aperture plates, wherein at least one of the plurality of differential aperture plates comprises a surface portion that is not perpendicular to an axis of the charged particle beam,
   wherein the surface portion is configured to guide gas molecules to the vacuum pump.
26. The apparatus of clause 25, wherein:
   the plurality of differential aperture plates comprises a first differential aperture plate and a second differential aperture plate that extends to a vacuum inlet of the vacuum pump.
27. The apparatus of clause 26, wherein:
   the plurality of differential aperture plates comprises a second differential aperture plate, and
   the first differential aperture plate and the second differential aperture plate form a channel that extends to the vacuum inlet of the vacuum pump.
28. The apparatus of clause 25, wherein the plurality of differential aperture plates comprises the electrode.
29. The apparatus of clause 25, wherein the plurality of differential aperture plates comprises an extractor electrode.
30. The apparatus of clause 25, wherein a differential aperture plate of the plurality of differential aperture plates comprises an electrically insulating material.
31. The apparatus of clause 25, wherein a differential aperture plate of the plurality of differential aperture plates comprises an electrically conductive central region and an electrically non-conductive peripheral region.
32. The apparatus of clause 25, wherein a dividing differential aperture plate of the plurality of differential aperture plates divides the vacuum chamber into a first chamber and a second chamber.
33. The apparatus of clause 32, wherein the plurality of differential aperture plates comprises a first differential aperture plate and a second differential aperture plate between the source and the dividing differential aperture plate.
34. The apparatus of clause 25, further comprising a booster tube configured to surround the charged particle beam within the vacuum chamber and generate an electric field inside the booster tube.
35. The apparatus of clause 34, wherein a differential aperture plate of the plurality of differential aperture plates is located inside the booster tube.
36. The apparatus of clause 25, wherein the plurality of differential aperture plates is arranged along an axial direction of the charged particle beam; each differential aperture plate comprising a hole, and
   wherein a size of the hole of each differential aperture plate of the plurality of differential aperture plates increases with increasing distance from the source.
37. An apparatus, comprising:
   a vacuum chamber;
   a vacuum pump;
   a source located inside the vacuum chamber and configured to emit charged particles;
   an electrode configured to accelerate the charged particles to generate a charged particle beam; and
   a plurality of differential aperture plates arranged along an axial direction of the charged particle beam, each differential aperture plate comprising a hole,
   wherein at least two differential aperture plates of the plurality of differential aperture plates comprise holes of different sizes, wherein a size of the holes of the at least two differential aperture plates increase with increasing distance from the source.
38. The apparatus of clause 37, wherein a size of the hole of each differential aperture plate of the plurality of differential aperture plates increases with increasing distance from the source.
39. The apparatus of clause 37, further comprising:
   a first differential aperture plate of the plurality of differential aperture plates;
   a second differential aperture plate of the plurality of differential aperture plates, and
   a third differential aperture plate of the plurality of differential aperture plates, the second differential aperture plate being located between the first differential aperture plate and the third differential aperture plate, wherein
   a second hole of the second aperture plate is smaller than a first hole of the first aperture plate and a third hole of the third aperture plate.
   wherein a size of the hole of each differential aperture plate of the plurality of differential aperture plates increases with increasing distance from the source
40. The apparatus of clause 39, wherein each of the first differential aperture plate, the second differential aperture plate, and the third differential aperture plate comprise one hole, the holes being the first hole of the first differential aperture plate, the second hole of the second differential aperture plate, and the third hole of the third differential aperture plate.
41. The apparatus of clause 37, wherein:
   the plurality of differential aperture plates comprises a first differential aperture plate and a second differential aperture plate that extends to a vacuum inlet of the vacuum pump.
42. The apparatus of clause 41, wherein:
   the plurality of differential aperture plates comprises a second differential aperture plate, and
   the first differential aperture plate and the second differential aperture plate form a channel that extends to the vacuum inlet of the vacuum pump.
43. The apparatus of clause 37, wherein the plurality of differential aperture plates comprises the electrode.
44. The apparatus of clause 37, wherein the plurality of differential aperture plates comprises an extractor electrode.
45. The apparatus of clause 37, wherein a differential aperture plate of the plurality of differential aperture plates comprises an electrically insulating material.
46. The apparatus of clause 37, wherein a differential aperture plate of the plurality of differential aperture plates comprises an electrically conductive central region and an electrically non-conductive peripheral region.
47. The apparatus of clause 37, wherein a dividing differential aperture plate of the plurality of differential aperture plates divides the vacuum chamber into a first chamber and a second chamber.
48. The apparatus of clause 47, wherein the plurality of differential aperture plates comprises a first differential aperture plate and a second differential aperture plate between the source and the dividing differential aperture plate.
49. The apparatus of clause 37, further comprising a booster tube configured to surround the charged particle beam within the vacuum chamber and generate an electric field inside the booster tube.
50. The apparatus of clause 49, wherein a differential aperture plate of the plurality of differential aperture plates is located inside the booster tube.
51. The apparatus of clause 37, wherein the plurality of differential aperture plates is configured to guide gas molecules to the vacuum pump.
52. An apparatus comprising:
   a vacuum chamber;
   a source located inside the vacuum chamber and configured to emit charged particles;
   an extractor at a first potential located downstream of the source, the extractor being at the first voltage to enable extraction of the electrons from the source;
   an anode, including multiple apertures each configured to generate a beamlet of charged particles from the emitted charged particles, located downstream from the extractor, the anode being at a second potential different from the first potential and causing energies of the beamlet of charged particles to change;
   a booster tube configured to reduce or eliminate disturbance of the beamlets due to electric fields of structures near to the booster tube, the booster tube being located downstream of the anode; and
   a differential aperture plate between the anode and the booster tube, the differential aperture plate being configured to reduce a flow of gas from the booster tube and flowing towards the source, the aperture plate being at the second potential.
53. The apparatus of clause 52, wherein the differential aperture plate is substantially planar.
54. The apparatus of clause 52, wherein the differential aperture plate comprises a surface portion that is not perpendicular to an axis of the charged particle beam.
55. The apparatus of clause 52, wherein the differential aperture plate extends to a vacuum inlet of the vacuum pump.
56. The apparatus of clause 52, further comprising:
   a second differential aperture plate, wherein the differential aperture plate and the second differential aperture plate form a channel configured to guide gas molecules to a vacuum pump of the vacuum chamber.
57. An apparatus, comprising:
   a vacuum chamber;
   an emission source located inside the vacuum chamber and configured to emit charged particles;
   a first aperture plate comprising a first plurality of holes, the first aperture plate being configured to block a portion of the emitted charged particles and pass the remaining emitted charged particles as a plurality of charged particle beamlets;
   a second aperture plate comprising a second plurality of holes and configured to pass the plurality of charged particle beamlets without blocking further charged particles; and an outgassing source;
   wherein the second aperture plate is configured to reduce passage of gas molecules from the outgassing source to the emission source.
58. The apparatus of clause 57, wherein the gas molecules cannot reach the emission source without passing through one of the second plurality of holes.
59. The apparatus of clause 57, wherein:
   each of the second plurality of holes is larger than the first plurality of holes.
60. The apparatus of clause 57, wherein:
   each of the second plurality of holes is smaller than the first plurality of holes.
61. The apparatus of clause 57, wherein the second aperture plate comprises a non-conductive material.
62. The apparatus of clause 57, further comprising:
   a component adjacent to the second aperture plate, the component being configured to generate an electric field at a point on a beam path of the plurality of charged particle beamlets;
   wherein the second aperture plate is configured to not disturb the electric field that is generated by the adjacent component at the point on the beam path.
63. The apparatus of clause 57, wherein the second aperture plate is configured to pass the plurality of charged particle beamlets without altering a beam property of the plurality of charged particle beamlets.
64. The apparatus of clause 63, wherein the beam property comprises one of a beam size, shape, energy, divergence and direction.
65. The apparatus of clause 64, wherein the second aperture plate is configured to pass the plurality of charged particle beamlets without altering any of a beam size, shape, energy, divergence and direction of the plurality of charged particle beamlets.
66. The apparatus of clause 57, further comprising:
   an opening at an exit side of the vacuum chamber, the opening having a width that is at least ten times larger than width of the second plurality of holes;
   wherein the second aperture plate is arranged at a downstream side of the opening in a beam propagation direction of the plurality of charged particle beamlets.
67. The apparatus of clause 66, wherein the opening comprises a gate valve.
68. The apparatus of clause 57, wherein the outgassing source comprises a charged particle optical component.
69. The apparatus of clause 68, wherein the charged particle optical component comprises a MEMS stack.
70. The apparatus of clause 57, wherein the outgassing source comprises a wiring component, a mounting component, a plastic component, an adhesive, a lubricant, or a seal.
71. The apparatus of clause 57, further comprising:
   a first charged particle optical component in the vacuum chamber; and
   a second charged particle optical component in the vacuum chamber,
   wherein the second aperture plate is provided between the first charged particle optical component and the second charged particle optical component.
72. The apparatus of clause 57, further comprising:
   a third aperture plate comprising a third plurality of holes, and configured to pass the plurality of charged particle beamlets without blocking further charged particles;
   wherein the third aperture plate is provided between the first aperture plate and the second aperture plate.
73. The apparatus of clause 72, wherein the gas molecules cannot reach the emission source without passing through one of the third plurality of holes.
74. The apparatus of clause 72, further comprising:
   a vacuum pump of the vacuum chamber;
   a space between the second aperture plate and the third aperture plate; and
   an exhaust path between the space and the vacuum pump,
   wherein the exhaust path does not include the second plurality of holes or the third plurality of holes.
75. The apparatus of clause 57, wherein the apparatus comprises an electron beam source.
76. The apparatus of clause 57, wherein the apparatus comprises an electron multi-beam inspection tool.
77. An apparatus, comprising:
   a vacuum chamber;
   an emission source located inside the vacuum chamber and configured to emit charged particles;
   a first aperture plate comprising a first hole, the first aperture plate being configured to block a portion of the emitted charged particles and pass the remaining emitted charged particles as a charged particle beam;
   a second aperture plate comprising a second hole and configured to pass the charged particle beam without blocking further charged particles; and
   an outgassing source;
   wherein the second aperture plate is configured to reduce passage of gas molecules from the outgassing source to the emission source.
78. The apparatus of clause 77, wherein the gas molecules cannot reach the emission source without passing through the second hole.
79. The apparatus of clause 77, wherein:
   the second hole is larger than the first hole.
80. The apparatus of clause 77, wherein:
   the first hole is larger than the second hole.
81. The apparatus of clause 77, wherein the second aperture plate comprises a non-conductive material.
82. The apparatus of clause 77, further comprising:
   a component adjacent to the second aperture plate, the component being configured to generate an electric field at a point on a beam path of the charged particle beam;
   wherein the second aperture plate is configured to not disturb the electric field that is generated by the adjacent component at the point on the beam path.
83. The apparatus of clause 77, wherein the second aperture plate is configured to pass the charged particle beam without altering a beam property of the charged particle beam.
84. The apparatus of clause 83, wherein the beam property comprises one of a beam size, shape, energy, divergence and direction.
85. The apparatus of clause 84, wherein the second aperture plate is configured to pass the charged particle beam without altering any of a beam size, shape, energy, divergence and direction of the charged particle beam.
86. The apparatus of clause 77, further comprising:
   an opening at an exit side of the vacuum chamber, the opening having a width that is at least ten times the width of the second hole;
   wherein the second aperture plate is arranged at a downstream side of the opening in a beam propagation direction of the charged particle beam.
87. The apparatus of clause 86, wherein the opening comprises a gate valve.
88. The apparatus of clause 77, wherein the outgassing source comprises a charged particle optical component.
89. The apparatus of clause 88, wherein the charged particle optical component comprises a MEMS stack.
90. The apparatus of clause 77, wherein the outgassing source comprises a wiring component, a mounting component, a plastic component, an adhesive, a lubricant, or a seal.
91. The apparatus of clause 77, further comprising:
   a first charged particle optical component in the vacuum chamber; and
   a second charged particle optical component in the vacuum chamber,
   wherein the second aperture plate is provided between the first charged particle optical component and the second charged particle optical component.
92. The apparatus of clause 77, further comprising:
   a third aperture plate comprising a third hole, and configured to pass the charged particle beam without blocking further charged particles;
   wherein the third aperture plate is provided between the first aperture plate and the second aperture plate.
93. The apparatus of clause 92, wherein the gas molecules cannot reach the emission source without passing through the third hole.
94. The apparatus of clause 92, further comprising:
   a vacuum pump of the vacuum chamber;
   a space between the second aperture plate and the third aperture plate; and
   an exhaust path between the space and the vacuum pump,
   wherein the exhaust path does not include the second hole or the third hole.
95. The apparatus of clause 77, wherein the apparatus comprises an electron beam source.
96. The apparatus of clause 77, wherein the apparatus comprises an electron beam inspection tool.
97. The apparatus of clause 57, wherein:
a space between the first aperture plate and the second aperture plate comprises an exhaust path in communication with a vacuum pump.
98. The apparatus of clause 57, wherein one of the first aperture plate and the second aperture plate comprises an electrode.
99. The apparatus of clause 57, wherein one of the first aperture plate and the second aperture plate comprises an extractor electrode.
100. The apparatus of clause 57, wherein one of the first aperture plate and the second aperture plate comprises an electrically insulating material.
101. The apparatus of clause 57, wherein one of the first aperture plate and the second aperture plate comprises an electrically conductive central region and an electrically non-conductive peripheral region.
102. The apparatus of clause 57, further comprising:
   a booster tube between the first aperture plate and the second aperture plate,
   wherein the booster tube is configured to surround the charged particle beam within the vacuum chamber and generate an electric field inside the booster tube.
103. The apparatus of clause 72, wherein each of the third plurality of holes is larger than each of the first plurality of holes and each of the second plurality of holes.
104. The apparatus of clause 72, wherein each of the third plurality of holes is larger than each of the first plurality of holes and each of the second plurality of holes.
105. The apparatus of clause 57, wherein at least one of first aperture plate and the second aperture plate is substantially planar.
106. An apparatus, comprising:
   a vacuum chamber;
   a source configured to emit charged particles;
   an electrode configured to accelerate the charged particles to generate a charged particle beam along an optical axis;
   a first booster tube configured to surround the optical axis within the vacuum chamber, the first booster tube comprising a first opening in a first sidewall of the first booster tube, the first opening being configured to allow gas molecules from inside the first booster tube to pass outside the first booster tube; and
   a second booster tube configured to surround the first booster tube within the vacuum chamber, the second booster tube comprising a second opening in a second sidewall of the second booster tube, the second opening being configured to allow gas molecules from inside the second booster tube to pass outside the second booster tube,
   wherein the first opening is completely offset from the second opening in a direction of the optical axis.
107. The apparatus of clause 106, wherein:
   the first booster tube comprises a plurality of the first openings arranged in a first plurality of rows in the first sidewall extending in an azimuthal direction around the optical axis; and
   the second booster tube comprises a plurality of the second openings arranged in a second plurality of rows in the second sidewall extending in the azimuthal direction around the optical axis.
108. The apparatus of clause 107, wherein:
   at least one row of the first plurality of rows comprises a first odd number of first openings, and
   at least one row of the second plurality of rows comprises a second odd number of second openings,
   wherein the first odd number is different from the second odd number.
109. The apparatus of clause 107, wherein:
   at least one row of the first plurality of rows comprises a first prime number of first openings, and
   at least one row of the second plurality of rows comprises a second prime number of second openings,
   wherein the first prime number is different from the second prime number.
110. The apparatus of clause 107, wherein at least two rows of first openings in the first plurality of rows are staggered from each other in the azimuthal direction by an azimuthal offset.
111. The apparatus of clause 110, wherein the azimuthal offset comprises one of substantially one quarter period of repetition, substantially one third period of repetition, or substantially one half period of repetition of the first openings in the azimuthal direction.
112. The apparatus of clause 107, wherein at least two rows of second openings in the second plurality of rows are staggered from each other in the azimuthal direction by an azimuthal offset.
113. The apparatus of clause 112, wherein the azimuthal offset comprises one of substantially one quarter period of repetition, substantially one third period of repetition, or substantially one half period of repetition of the second openings in the azimuthal direction.
114. The apparatus of clause 107, wherein at least two rows of first openings in the first plurality of rows have different opening sizes from each other.
115. The apparatus of clause 107, wherein a size of the first openings in the first plurality of rows decreases along the direction of the optical axis.
116. The apparatus of clause 107, wherein at least two rows of second openings in the second plurality of rows have different opening sizes from each other.
117. The apparatus of clause 107, wherein a size of the second openings in the second plurality of rows decreases along the direction of the optical axis.
118. The apparatus of clause 107, wherein one of the plurality of first openings and the plurality of plurality openings comprises an elliptical shape.
119. The apparatus of clause 106, wherein the first opening comprises an elongated slit extending in the azimuthal direction around the optical axis.
120. The apparatus of clause 106, wherein the second opening comprises an elongated slit extending in the azimuthal direction around the optical axis.
121. The apparatus of clause 106, wherein:
   the first booster tube comprises a first thickness, and
   the second booster tube comprises a second thickness,
   wherein the first thickness is different from the second thickness.
122. The apparatus of clause 106, wherein:
   the first booster tube comprises a first material, and
   the second booster tube comprises a second material,
   wherein the first material is different from the second material.
123. The apparatus of clause 106, wherein:
   the first booster tube comprises a first permeability, and
   the second booster tube comprises a second permeability,
   wherein the first permeability is different from the second permeability.
124. The apparatus of clause 106, wherein:
   the first booster tube comprises a first conductivity, and
   the second booster tube comprises a second conductivity,
   wherein the first conductivity is different from the second conductivity.
125. The apparatus of clause 106, further comprising:
   a magnetic optical element configured to generate an electromagnetic field in a region of the optical axis inside the first booster tube and the second booster tube.
126. The apparatus of clause 125, wherein:
   the magnetic optical element is configured to operate over a working frequency bandwidth; and
   one of the first booster tube and the second booster tube comprises a skin depth frequency that is outside the working frequency bandwidth.
127. The apparatus of clause 126, wherein the other of the first booster tube and the second booster tube comprises a further skin depth frequency that is outside the working frequency bandwidth.
128. The apparatus of clause 126, wherein the other of the first booster tube and the second booster tube comprises a further skin depth frequency that is inside the working frequency bandwidth.
129. The apparatus of clause 125, wherein the first booster tube and the second booster tube are configured to reduce a non-uniformity of the electromagnetic field with respect to a configuration in which the first opening is not completely offset from the second opening in the direction of the optical axis.

A non-transitory computer-readable medium may be provided that stores instructions for a processor of a controller (e.g., controller 109 in FIG. 1A, or image processing system 121 of FIG. 1B) for detecting charged particles according to, e.g., the exemplary flowcharts of FIGS. 8 and 12, consistent with embodiments of the present disclosure. For example, the instructions stored in the non-transitory computer-readable medium may be executed by the circuitry of the controller for performing method 800 or method 1200 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof. For example, a charged particle inspection system may be but one example of a charged particle beam system consistent with embodiments of the present disclosure.

1. An apparatus, comprising:
a vacuum chamber;
an emission source located inside the vacuum chamber and configured to emit charged particles;
a first aperture plate comprising a first plurality of holes, the first aperture plate being configured to block a portion of the emitted charged particles and pass the remaining emitted charged particles as a plurality of charged particle beamlets;
a second aperture plate comprising a second plurality of holes and configured to pass the plurality of charged particle beamlets without blocking further charged particles; and
an outgassing source;
wherein the second aperture plate is configured to reduce passage of gas molecules from the outgassing source to the emission source.

2. The apparatus of claim 1, wherein the gas molecules cannot reach the emission source without passing through one of the second plurality of holes.

3. The apparatus of claim 1, wherein: each of the second plurality of holes is larger than the first plurality of holes.

4. The apparatus of claim 1, wherein:
each of the second plurality of holes is smaller than the first plurality of holes.

5. The apparatus of claim 1, further comprising:
a component adjacent to the second aperture plate, the component being configured to generate an electric field at a point on a beam path of the plurality of charged particle beamlets;
wherein the second aperture plate is configured to not disturb the electric field that is generated by the adjacent component at the point on the beam path.

6. The apparatus of claim 1, wherein the second aperture plate is configured to pass the plurality of charged particle beamlets without altering a beam property of the plurality of charged particle beamlets.

7. The apparatus of claim 1, wherein the second aperture plate is configured to pass the plurality of charged particle beamlets without altering any of a beam size, shape, energy, divergence and direction of the plurality of charged particle beamlets.

8. The apparatus of claim 1, further comprising:
an opening at an exit side of the vacuum chamber, the opening having a width that is at least ten times larger than width of the second plurality of holes;
wherein the second aperture plate is arranged at a downstream side of the opening in a beam propagation direction of the plurality of charged particle beamlets.

9. The apparatus of claim 1, wherein the outgassing source comprises a charged particle optical component.

10. The apparatus of claim 1, further comprising:
a third aperture plate comprising a third plurality of holes, and configured to pass the plurality of charged particle beamlets without blocking further charged particles;
wherein the third aperture plate is provided between the first aperture plate and the second aperture plate.

11. The apparatus of claim 10, wherein the gas molecules cannot reach the emission source without passing through one of the third plurality of holes.

12. The apparatus of claim 10, further comprising:
a vacuum pump of the vacuum chamber;
a space between the second aperture plate and the third aperture plate; and
an exhaust path between the space and the vacuum pump,
wherein the exhaust path does not include the second plurality of holes or the third plurality of holes.

13. The apparatus of claim 1, wherein one of the first aperture plate and the second aperture plate comprises an electrode.

14. The apparatus of claim 1, wherein one of the first aperture plate and the second aperture plate comprises an electrically insulating material.

15. The apparatus of claim 1, wherein one of the first aperture plate and the second aperture plate comprises an electrically conductive central region and an electrically non-conductive peripheral region.

16. An apparatus, comprising:
a vacuum chamber;
a source located inside the vacuum chamber and configured to emit charged particles;
an electrode configured to accelerate the charged particles to generate a charged particle beam; and
a booster tube configured to surround the charged particle beam within the vacuum chamber and generate a uniform potential inside the booster tube, the booster tube comprising an opening configured to allow gas molecules from inside the booster tube to pass to a region outside the booster tube, the region being adjacent to the booster tube in a radial direction perpendicular to an axis of the charged particle beam.

17. The apparatus of claim 16, wherein the opening comprises a hole in a sidewall of the booster tube.

18. The apparatus of claim 16, wherein the booster tube comprises a first booster tube segment and a second booster tube segment; and
the opening comprises a gap between the first booster tube segment and the second booster tube segment.

19. The apparatus of claim 18, wherein the first booster tube segment and the second booster tube segment comprise tubular booster tube segments configured to substantially surround a portion of the charged particle beam.

20. The apparatus of claim 19, wherein the first booster tube segment has a different diameter than the second booster tube segment.
